(19) United States
(12) Patent Application Publication
(10) Pub. No.: US 2025/0089475 A1
(43) Pub. Date: Mar. 13, 2025

(54) DISPLAY DEVICE AND METHOD FOR MANUFACTURING THE SAME

(71) Applicant: Samsung Display Co., LTD., Yongin-si (KR)

(72) Inventors: Geun Chul PARK, Yongin-si (KR); So Young KOO, Yongin-si (KR); Jong Do KEUM, Yongin-si (KR); Eok Su KIM, Yongin-si (KR); Hyung Jun KIM, Yongin-si (KR); Joon Seok PARK, Yongin-si (KR); Ae Ran SONG, Yongin-si (KR)

(21) Appl. No.: 18/635,753

(22) Filed: Apr. 15, 2024

(30) Foreign Application Priority Data
Sep. 13, 2023 (KR) 10-2023-0121490

(51) Int. Cl. H10K 59/124; H01L 27/12; H10K 59/12

(52) U.S. Cl. CPC H10K 59/124; H10K 59/1201; H10D 86/423; H10D 86/451; H10D 86/60

(57) ABSTRACT

A display device includes a substrate, a first transistor including a first active layer disposed on the substrate and a first gate electrode disposed on the first active layer, and a first gate insulating layer disposed between the first active layer and the first gate electrode. The first active layer includes an oxide semiconductor containing indium (In) at a content range of about 40 at % to about 54 at %, and the first gate insulating layer has an emission amount range of oxygen (O₂) of about 2.48E+19 Molec./cm³ to about 2.76E+19 Molec./cm³, or an emission amount range of nitrogen monoxide (NO) of about 1.04E+20 Molec./cm³ to about 1.15E+20 Molec./cm³ under heat treatment conditions performed at a temperature range of about 50° C. to about 550° C.

This application claims priority to Korean Patent Application No. 10-2023-0121490, filed on Sep. 13, 2023, and all the benefits accruing therefrom under 35 U.S.C. § 119, the contents of which in their entirety are herein incorporated by reference.

### BACKGROUND

### 1. Technical Field

The invention relates to a display device, and more particularly to a display device and a method for manufacturing the same.

### 2. Description of the Related Art

The importance of display devices has steadily increased with the development of multimedia technology. Accordingly, various types of display devices such as a liquid crystal display device or a light emitting display device have been developed.

### SUMMARY

Aspects of the invention provide a display device including an oxide semiconductor and a method for manufacturing the same.

Aspects of the invention are not restricted to the embodiments set forth herein. The above and other aspects of the invention will become more apparent to one of ordinary skill in the art to which the invention pertains by referencing the detailed description of the invention given below.

According to an embodiment, there is provided a display device including a substrate, a first transistor including a first active layer disposed on the substrate and a first gate electrode disposed on the first active layer, and a first gate insulating layer disposed between the first active layer and the first gate electrode. The first active layer includes an oxide semiconductor containing indium (In) at a content range of about 40 at % to about 54 at %, and the first gate insulating layer has an emission amount of oxygen (O₂) in a range of about 2.48E+19 Molec./cm³ to about 2.76E+19 Molec./cm³, or an emission amount of nitrogen monoxide (NO) in a range of about 1.04E+20 Molec./cm³ to about 1.15E+20 Molec./cm³ under heat treatment conditions performed at a temperature range of about 50° C. to about 550° C.

In an embodiment, the first active layer may further contain at least one of gallium (Ga), zinc (Zn), and tin (Sn).

In an embodiment, the first active layer may contain indium-gallium-zinc oxide (IGZO), indium-tin-gallium oxide (ITGO), or indium-tin-gallium-zinc oxide (ITGZO).

In an embodiment, the first gate insulating layer may contain silicon oxide.

In an embodiment, the display device may further include a pixel, the pixel including a pixel circuit including the first transistor and a light emitting element connected to the pixel circuit.

In an embodiment, the pixel may further include, a second transistor including a second active layer disposed on the substrate and a second gate electrode disposed on the second active layer, and a second gate insulating layer disposed between the second active layer and the second gate electrode.

In an embodiment, the second active layer may be disposed in a same layer as the first active layer and contain a same oxide semiconductor as the first active layer.

In an embodiment, the second gate insulating layer may be disposed in a same layer as the first gate insulating layer and contain a same insulating material as the first gate insulating layer.

In an embodiment, the display device may further include a driver disposed on the substrate and electrically connected to the pixel.

In an embodiment, the driver may include, a third transistor including a third active layer disposed on the substrate and containing a same oxide semiconductor as the first active layer and a third gate electrode disposed on the third active layer, and a third gate insulating layer disposed between the third active layer and the third gate electrode and containing a same insulating material as the first gate insulating layer.

In an embodiment, the first active layer may include a first channel region overlapping the first gate electrode, and a first drain region and a first source region located on both sides of the first channel region, and the first gate insulating layer may be an insulating pattern disposed only on a portion of the first active layer including the first channel region and exposing the first drain region and the first source region.

In an embodiment, the display device may further include an interlayer insulating layer disposed on the substrate and covering the first active layer and the first gate electrode, wherein the first transistor may further include at least one of a first drain electrode disposed on the interlayer insulating layer and connected to a part of the first active layer, and a first source electrode disposed on the interlayer insulating layer and connected to another part of the first active layer.

In an embodiment, the display device may further include a first passivation layer disposed on the interlayer insulating layer and covering the first transistor.

In an embodiment, the first passivation layer may include an inorganic insulating layer containing silicon nitride.

In an embodiment, the display device may further include a second passivation layer disposed on the first passivation layer. The first passivation layer may include an inorganic insulating layer containing silicon oxide, and the second passivation layer may include an inorganic insulating layer containing silicon nitride.

In an embodiment, the first transistor may have an electron mobility in a range of about 20 cm²/Vs to about 50 cm²/Vs.

In an embodiment, the first transistor may have a threshold voltage in a range of about −1.0 V to about +0.5 V.

According to an embodiment, there is provided a method for manufacturing a display device, including forming an active layer on a substrate, forming a gate insulating layer on the active layer, and forming a gate electrode on the gate insulating layer. In the forming of the active layer, the active layer is formed using an oxide semiconductor containing indium (In) at a content range of about 40 at % to about 54 at %, and in the forming of the gate insulating layer, the gate insulating layer is formed by depositing an insulating material containing oxide on the substrate on which the active layer is formed at a pressure of about 1400 mTorr to about 1500 mTorr.

In an embodiment, the method may further include etching the gate insulating layer to have a shape corresponding to that of the gate electrode.

In an embodiment, the method may further include forming an interlayer insulating layer covering the active layer and the gate electrode and forming at least one of a drain electrode connected to a part of the active layer or a source electrode connected to another part of the active layer, on the interlayer insulating layer.

A display device according to an embodiment includes a first transistor including a first active layer and a first gate electrode disposed on the first active layer, and a first gate insulating layer disposed between the first active layer and the first gate electrode. The first active layer may include an oxide semiconductor containing indium (In) at a content range of about 40 at % to about 54 at %, and the first gate insulating layer may have characteristics in which an emission amount range of nitrogen monoxide (NO) is about 1.04E+20 Molec./cm³ to about 1.15E+20 Molec./cm³ or an emission amount range of oxygen (O₂) is about 2.48E+19 Molec./cm³ to about 2.76E+19 Molec./cm³.

According to an embodiment, it is possible to appropriately control and/or secure the element characteristics of a transistor while forming the transistor with a relatively simple structure by using a high-mobility oxide semiconductor. In an embodiment, by controlling the content of indium (In) contained in the oxide semiconductor forming the active layer and the characteristics of the gate insulating layer related to the emission amount of nitrogen monoxide (NO) or oxygen (O₂), the electrical characteristics of the transistor may be appropriately and/or easily controlled. Accordingly, a transistor having element characteristics suitable for a display panel may be formed using a high-mobility oxide semiconductor without forming an additional layer for supplying oxygen to the active layer. As a result, the structure and manufacturing process of the display device may be simplified and/or streamlined, and the manufacturing efficiency of the display device may be increased. In addition, by forming a transistor using a high-mobility oxide semiconductor, appropriate element characteristics may be secured although the transistor is formed in a fine size. Accordingly, it is possible to easily manufacture a high-resolution display device.

Effects according to embodiments of the invention are not limited to those exemplified above and various other effects are incorporated herein.

### BRIEF DESCRIPTION OF THE DRAWINGS

The above and other aspects and features of the invention will become more apparent by describing in detail exemplary embodiments thereof with reference to the attached drawings, in which:

FIG. 1 is a plan view illustrating a display device, according to an embodiment;

FIG. 2 is a plan view illustrating the display panel of FIG. 1, according to an embodiment;

FIG. 3 is a circuit diagram illustrating a pixel, according to an embodiment;

FIG. 4 is a cross-sectional view illustrating a display panel, according to an embodiment;

FIG. 5 is a cross-sectional view illustrating a display panel, according to an embodiment;

FIG. 6 is a cross-sectional view illustrating a display panel, according to an embodiment;

FIG. 7 is a graph illustrating changes in the characteristics of a transistor depending on the content of indium (In) contained in an active layer of a transistor and a deposition pressure of a gate insulating layer, according to an embodiment;

FIG. 8 is a graph illustrating changes in the characteristics of a transistor depending on the content of indium (In) contained in an active layer of a transistor and a deposition pressure of a gate insulating layer, according to an embodiment;

FIG. 9 is a bar chart illustrating the emission amount of nitrogen monoxide according to the deposition pressure of the gate insulating layer, according to an embodiment;

FIG. 10 is a bar chart illustrating the emission amount of oxygen according to the deposition pressure of the gate insulating layer, according to an embodiment;

FIG. 11 is a cross-sectional view illustrating a method for manufacturing the display device, according to an embodiment;

FIG. 12 is a cross-sectional view illustrating a method for manufacturing the display device, according to an embodiment;

FIG. 13 is a cross-sectional view illustrating a method for manufacturing the display device, according to an embodiment;

FIG. 14 is a cross-sectional view illustrating a method for manufacturing the display device, according to an embodiment;

FIG. 15 is a cross-sectional view illustrating a method for manufacturing the display device, according to an embodiment;

FIG. 16 is a cross-sectional view illustrating a method for manufacturing the display device, according to an embodiment;

FIG. 17 is a cross-sectional view illustrating a method for manufacturing the display device, according to an embodiment; and

FIG. 18 is a cross-sectional view illustrating a method for manufacturing the display device, according to an embodiment.

### DETAILED DESCRIPTION

The present invention will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art.

It will also be understood that when an element or a layer is referred to as being “on” another element or layer, it can be directly on the other element or layer, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the present invention. Similarly, the second element could also be termed the first element.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. In addition, unless explicitly described to the contrary, the word “comprise,” and variations such as “comprises” or “comprising,” will be understood to imply the inclusion of stated elements but not the exclusion of any other elements.

The terms “about” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the invention.

Features of each of various embodiments may be partially or entirely combined with each other and may technically variously interwork with each other, and respective embodiments may be implemented independently of each other or may be implemented together in association with each other.

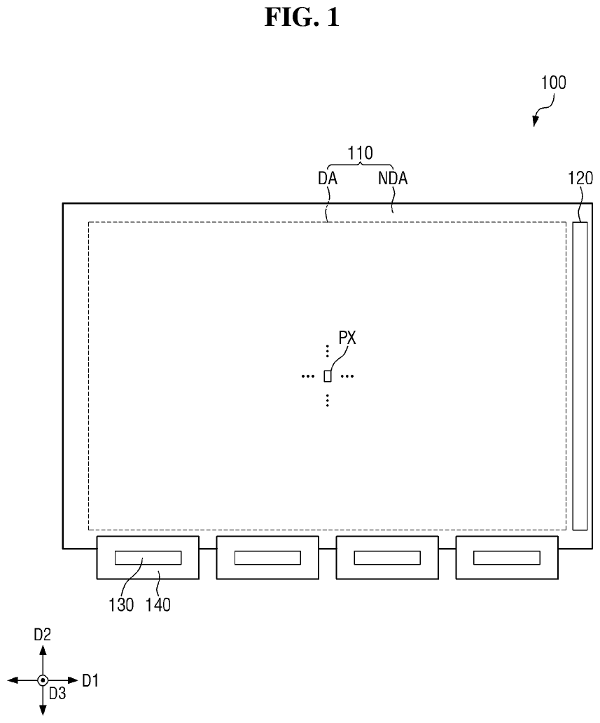

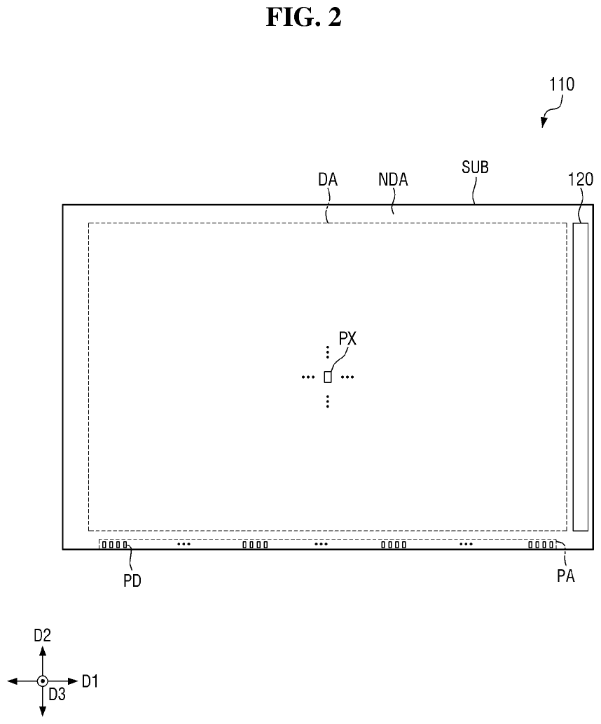

FIG. 1 is a plan view illustrating a display device 100, according to an embodiment. FIG. 2 is a plan view illustrating the display panel 110 of FIG. 1, according to an embodiment.

In an embodiment and referring to FIGS. 1 and 2, the display device 100 is a device for displaying a moving image or a still image. The display device 100 may be used as a display screen of various devices, such as a television, a laptop computer, a monitor, a billboard and an Internet-of-Things (IOT) device, as well as portable electronic devices such as a mobile phone, a smartphone, a tablet personal computer (PC), a smart watch, a watch phone, a mobile communication terminal, an electronic notebook, an electronic book, a portable multimedia player (PMP), a navigation device and an ultra-mobile PC (UMPC). These are presented as nothing more than examples, and the display device 100 may be applicable to various other types of electronic devices.

In an embodiment, the display device 100 may be a light emitting display device such as an organic light emitting display including an organic light emitting diode, a quantum dot light emitting display including a quantum dot light emitting layer, an inorganic light emitting display including an inorganic semiconductor, or an ultra-small light emitting display using an ultra-small light emitting diode such as a micro or nano light emitting diode (micro LED or nano LED), but is not limited thereto. For example, the display device 100 may be of a type other than the light emitting display device. In the following, embodiments in which the display device 100 is an organic light emitting display device will be disclosed.

In an embodiment, the display device 100 may include the display panel 110 including pixels PX, and a first driver 120 and a second driver 130 configured to supply driving signals to the pixels PX. The display device 100 may further include additional components. For example, the display device 100 may further include a power supply unit for supplying power voltages to the pixels PX, the first driver 120, and the second driver 130, and a timing controller for controlling the operations of the first driver 120 and the second driver 130.

In an embodiment, the display panel 110 may include a display area DA and a non-display area NDA (also referred to as a “bezel area”). The display area DA may be an area including the pixels PX to display an image. The non-display area NDA is an area other than the display area DA, and an image may not be displayed in the non-display area NDA. In an embodiment, the non-display area NDA may be positioned around the display area DA and may surround the display area DA.

In an embodiment and referring to FIGS. 1 and 2, a first direction D1, a second direction D2, and a third direction D3 are defined. In an embodiment, the first direction D1 and the second direction D2 may be perpendicular to each other, the first direction D1 and the third direction D3 may be perpendicular to each other, and the second direction D2 and the third direction D3 may be perpendicular to each other. For example, the first direction D1 may be the horizontal direction (for example, a row direction or X direction) of the display panel 110, and the second direction D2 may be the vertical direction (for example, a column direction or Y direction) of the display panel 110. The third direction D3 may be the thickness direction (for example, a height direction or Z direction) of the display panel 110.

In an embodiment, the display panel 110 may have a rectangular shape in a plan view. For example, the display panel 110 may include two first sides extending in the first direction D1 and two second sides extending in the second direction D2 intersecting the first direction D1. Although FIGS. 1 and 2 illustrate the display panel 110 in which the first side in the horizontal direction is longer than the second side in the vertical direction, the shape of the display panel 110 is not limited thereto. For example, the display panel 110 may have a shape in which the second side in the vertical direction is longer than the first side in the horizontal direction, or the lengths of the first side and the second side are substantially the same.

In an embodiment, the display panel 110 may include an angled corner at a portion where the first side and the second side meet, but the present disclosure is not limited thereto. For example, the display panel 110 may include a rounded corner at a portion where the first side and the second side meet.

In an embodiment, the planar shape of the display panel 110 is not limited to the illustrated rectangular shape, and it may be applied in other shapes. For example, the display panel 110 may have a square shape, a non-quadrilateral polygonal shape, a circular shape, an elliptical shape, an atypical shape, or another shape in a plan view.

In an embodiment, the display panel 110 may be substantially flat on the plane defined by the first direction D1 and the second direction D2, and may have a uniform thickness in the third direction D3. In another embodiment, the display panel 110 may be provided in a three-dimensional shape having a curved surface or the like.

In an embodiment, the display panel 110 may be provided as a panel having rigid characteristics so as not to be substantially deformed, or as a panel having flexible characteristics that can be transformed to be at least partially folded, bent, or rolled. The display panel 110 may be provided to the display device 100 without bending, or may be provided to the display device 100 while being partially bent.

In an embodiment, the display panel 110 may include a substrate SUB and pixels PX disposed on the substrate SUB. The pixels PX may be disposed in the display area DA on the substrate SUB.

In an embodiment, the substrate SUB may be a base member for manufacturing or providing the display panel 110, and may constitute a base surface of the display panel 110. The substrate SUB may include the display area DA and the non-display area NDA located around the display area DA.

The display area DA may have various shapes depending on embodiments. For example, in an embodiment, the display area DA may have a quadrilateral shape, a non-quadrilateral polygonal shape, a circular shape, an elliptical shape, an atypical shape, or another shape. In another embodiment, the display area DA may have a shape corresponding to the shape of the display panel 110, but the present disclosure is not limited thereto.

In an embodiment, the display area DA may include pixel areas where the pixels PX are provided and/or disposed. For example, each pixel PX may be disposed in each pixel area located in the display area DA. In one embodiment, the display device 100 may be a light emitting display device, and each pixel PX may include a light emitting element located in each emission area and a pixel circuit connected to the light emitting element. In describing embodiments, the term “connect” may include electrical connection and/or physical connection.

In an embodiment, each pixel area may include an emission area where the light emitting element of the corresponding pixel is located and where the pixel emits light, and a pixel circuit area where circuit elements constituting the pixel circuit of the corresponding pixel are located. In an embodiment, the emission area and the pixel circuit area of each pixel PX may overlap each other, but the invention is not limited thereto.

In an embodiment, the pixels PX may be arranged in the display area DA. For example, the pixels PX may be arranged in the display area DA in a stripe structure, a delta structure, a pentile structure, or other arrangement structures.

In an embodiment, the non-display area NDA may include a driving circuit area located on at least one side of the display area DA and a pad area PA where pads PD are disposed. At least one driver, the pads PD, and/or wires may be disposed in the non-display area NDA.

In an embodiment, at least one driver for driving the pixels PX, or a part of the driver may be disposed in the driving circuit area. For example, the circuit elements constituting the first driver 120 may be disposed in the driving circuit area on the substrate SUB. In one embodiment, the circuit elements of the first driver 120 may be formed in the display panel 110 together with the pixels PX.

In an embodiment, the pads PD may be disposed in the pad area PA. At least one circuit board 140 may be disposed and/or bonded on the pad area PA. In one embodiment, a plurality of circuit boards 140 connected to different pads PD may be disposed on the pad area PA. The pads PD may include signal pads and power pads for transmitting driving signals and power voltages required for driving the pixels PX and/or the first driver 120 into the display panel 110.

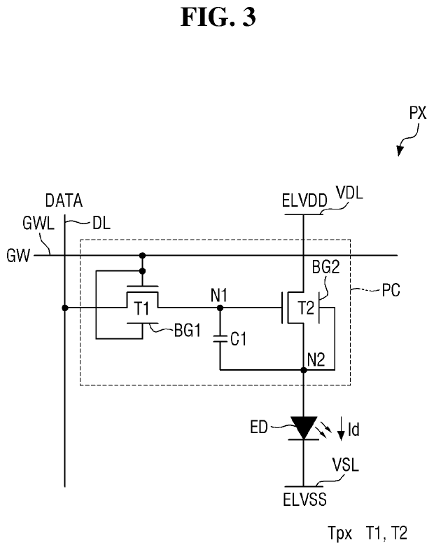

In an embodiment, the first driver 120 and the second driver 130 may generate driving signals for controlling operation timing, luminance, and the like of the pixels PX, and may supply the generated driving signals to the pixels PX. For example, the first driver 120 may be a gate driver including a scan driver and may be connected to the pixels PX through respective gate lines. The first driver 120 may provide gate signals (for example, driving signals that control the operation timing of the pixels PX, such as a gate signal GW of FIG. 3) to the pixels PX. The second driver 130 may be a data driver including source driving circuits and may be connected to the pixels PX through respective data lines. The second driver 130 may supply respective data signals to the pixels PX.

In an embodiment, at least one first driver of the first driver 120 or the second driver 130, or a part of the at least one first driver may be embedded in the display panel 110. For example, the first driver 120 or a part of the first driver 120 may be disposed and/or formed in the non-display area NDA and disposed on the substrate SUB of the display panel 110.

In an embodiment, although FIG. 1 illustrates that the first driver 120 is formed on one side of the display area DA (for example, in the non-display area NDA on the right side of the display area DA), the invention is not limited thereto. For example, the first driver 120 may be positioned only on the other side (e.g., the non-display area NDA on the left side of the display area DA) of the display area DA, or may be positioned on both sides (e.g., the non-display area NDA on the left side and right side of the display area DA) of the display area DA. In another embodiment, a part of the first driver 120 (for example, some of circuit elements constituting the first driver 120) are located in the non-display area NDA, and another part of the first driver 120 (for example, the rest of the circuit elements constituting the first driver 120) may be located in a non-emission area (for example, an area between emission areas of the pixels PX) inside the display area DA.

In an embodiment, the other driver of the first driver 120 and the second driver 130 or a part of the other driver may be disposed or formed outside the display panel 110 to be electrically connected to the display panel 110. For example, the second driver 130 or a part of the second driver 130 may be implemented by a multiple number of integrated circuit chips, and may be placed on the circuit board 140 electrically connected to the pixels PX of the display panel 110. In one embodiment, the second driver 130 and the timing controller may be integrated into separate integrated circuits or may be integrated into one integrated chip. The second driver 130 may be implemented as at least one integrated circuit chip and mounted on the non-display area NDA of the display panel 110.

In an embodiment, the circuit board 140 may be connected to the display panel 110 through the pads PD. In an embodiment, the circuit board 140 may be a flexible film such as a flexible printed circuit board (FPCB), a printed circuit board (PCB), or a chip on film (COF), but is not limited thereto. In an embodiment, the circuit board 140 may be connected to the timing controller and/or the power supply unit through another circuit board, connector, or the like.

FIG. 3 is a circuit diagram illustrating the pixel PX, according to an embodiment. The pixel PX of FIG. 3 is merely presented as one example, and the structure or type of the pixel PX may be variously changed according to embodiments.

In an embodiment and referring to FIG. 3 in addition to FIGS. 1 and 2, the pixel PX may include a light emitting element ED, and a pixel circuit PC connected to the light emitting element ED. The light emitting element ED is a light source of the pixel PX, and it may be, for example, an organic light emitting diode, but is not limited thereto. The pixel circuit PC may control the emission of the light emitting element ED by supplying a driving current Id corresponding to a data signal DATA to the light emitting element ED.

In an embodiment, the pixel circuit PC may include pixel transistors Tpx and at least one capacitor C1. For example, the pixel circuit PC may include a first transistor T1, a second transistor T2, and the capacitor C1. The structure of the pixel circuit PC or the type and number of the circuit elements constituting the pixel circuit PC may be variously changed according to embodiments. For example, the pixel circuit PC may additionally further include at least one other pixel transistor and/or at least one other capacitor. FIG. 3 illustrates an embodiment in which all pixel transistors Tpx are N-type transistors. However, the types of the pixel transistors Tpx are not limited thereto. For example, at least one pixel transistor Tpx may be formed as a P-type transistor.

In an embodiment, the pixel circuit PC may supply the driving current Id to the light emitting element ED in response to the driving signals supplied from the first driver 120 and the second driver 130. For example, the pixel circuit PC may supply the driving current Id to the light emitting element ED to correspond to at least one gate signal GW (e.g., a scan signal that selects the pixels PX of each horizontal line) supplied from the first driver 120 through at least one gate line GWL (e.g., a scan line connected to the pixels PX of each horizontal line), and the data signal DATA supplied from the second driver 130 through the data line DL.

In an embodiment, the first transistor T1 may be a switching transistor that turns on or turns off depending on the gate-source voltage. The second transistor T2 may be a driving transistor of the pixel PX whose magnitude of drain-source current (e.g., the driving current Id) is determined depending on the gate-source voltage. Depending on the type (e.g., P-channel or N-channel transistor) and/or operating conditions of each of the first transistor T1 and the second transistor T2, the first electrode of each of the first transistor T1 and the second transistor T2 may be a drain electrode (or drain region) or a source electrode (or source region), and the second electrode thereof may be an electrode different from the first electrode. For example, when the first electrode of the first transistor T1 is a drain electrode, the second electrode of the first transistor T1 may be a source electrode.

In an embodiment, the pixel PX may be connected to the gate line GWL (e.g., scan line) that transmits the gate signal GW (e.g., scan signal) and the data line DL that transmits the data signal DATA. Further, the pixel PX may be connected to a first pixel power line VDL that transmits a first pixel voltage ELVDD (also referred to as “first pixel power voltage”), and a second pixel power line VSL that transmits a second pixel voltage ELVSS (also referred to as “second pixel power voltage”).

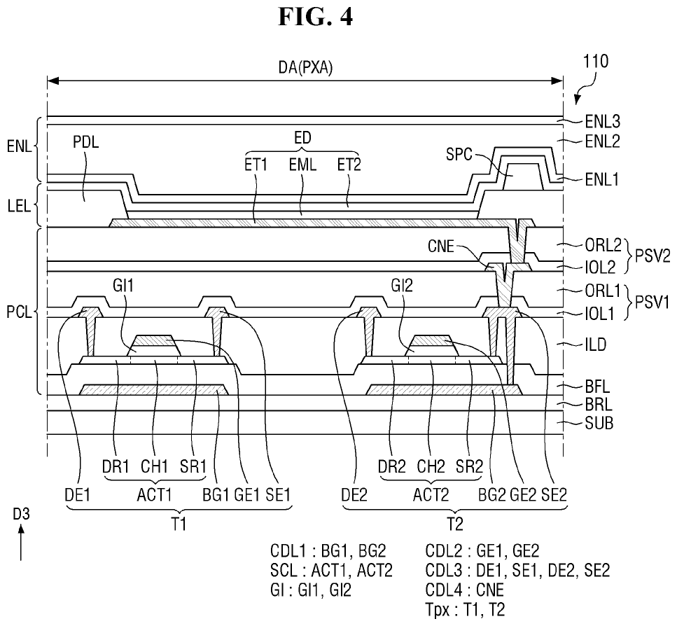

In an embodiment, the first transistor T1 and the second transistor T2 may be located in respective pixel areas (e.g., a pixel area PXA of any one pixel PX provided in the display area DA of FIG. 4), and may be oxide transistors (also referred to as “oxide semiconductor transistors”) including an oxide semiconductor (for example, an oxide semiconductor material). For example, the active layer (also called “active pattern” or “semiconductor pattern”) of each of the first transistor T1 and the second transistor T2 may be formed of an oxide semiconductor. However, the invention is not limited thereto. For example, at least one pixel transistor Tpx may be formed of a semiconductor material (for example, amorphous silicon or polysilicon) other than an oxide semiconductor.

In an embodiment, the oxide semiconductor has high carrier mobility (for example, high electron mobility in the case of an N-type transistor) and low leakage current, so even if a driving time of the oxide transistor is long, a voltage drop may not be large. For example, the pixel PX including an oxide transistor may be driven at a low frequency because the change in the luminance and/or the color of an image due to a voltage drop is not significant even when it is driven at a low frequency. In the case of the display device 100 in which the pixel transistors Tpx include an oxide semiconductor, the leakage current of the pixel PX may be reduced or prevented and the power consumption may be reduced.

In an embodiment, a lower electrode (also called a “back-gate electrode,” “counter gate electrode,” or “bottom electrode”) may be disposed below the active layer constituting at least one pixel transistor Tpx. For example, external light may be blocked by disposing a lower electrode under the active layer of the pixel transistor Tpx containing an oxide semiconductor. The lower electrode may be disposed to face the gate electrode with the active layer of the corresponding pixel transistor Tpx interposed therebetween.

In an embodiment, the pixel transistors Tpx may include respective lower electrodes. For example, the first transistor T1 may include a first lower electrode BG1, and the second transistor T2 may include a second lower electrode BG2. By providing lower electrodes to the pixel transistors Tpx, it is possible to prevent or reduce fluctuations in the current amount of the pixel transistors Tpx due to light and to stabilize the operating characteristics of the pixel transistors Tpx.

In an embodiment, the first transistor T1 may include a gate electrode connected to the gate line GWL, a first electrode connected to the data line DL, and a second electrode connected to the first node N1. The first transistor T1 may be turned on by the gate signal GW (e.g., a scan signal of the gate-on voltage) transmitted to the gate line GWL and may connect the data line DL to the first node N1. Accordingly, the data signal DATA transmitted through the data line DL may be sent to the first node N1.

In an embodiment, the first transistor T1 may further include the first lower electrode BG1 (or a first back-gate electrode). In an embodiment, the first lower electrode BG1 may be connected to one electrode of the first transistor T1, for example, the gate electrode. When the first lower electrode BG1 is connected to the gate electrode of the first transistor T1, the operating characteristics of the first transistor T1 may be improved and/or stabilized. For example, by forming the first transistor T1 in a double gate structure, it is possible to improve the off characteristics and switching speed of the first transistor T1, secure an additional voltage tolerance range, lower leakage current, and improve voltage stability.

In an embodiment, the second transistor T2 may include a gate electrode connected to the first node N1 (or a gate node), a first electrode (for example, a drain electrode or a drain region) connected to the first pixel power line VDL, and a second electrode (for example, a source electrode or a source region) connected to a second node N2. The second node N2 may be a node connected to the light emitting element ED. The second transistor T2 may control the magnitude (e.g., current amount) of the driving current Id flowing to the light emitting element ED to correspond to the data signal DATA transmitted according to the switching operation of the first transistor T1.

In an embodiment, the second transistor T2 may further include the second lower electrode BG2. For example, the second transistor T2 may further include the second lower electrode BG2 (or a second back-gate electrode) connected to the second node N2. When the second lower electrode BG2 is connected to the second node N2 like the second electrode of the second transistor T2, the operating characteristics of the second transistor T2 may be improved.

In an embodiment, the capacitor C1 may be connected between the first node N1 and the second node N2. For example, the capacitor C1 may be connected between the second electrode and the gate electrode of the second transistor T2. The capacitor C1 may be a storage capacitor of the pixel PX and may store a voltage corresponding to the data signal DATA (e.g., data voltage).

In an embodiment, the light emitting element ED may be connected between the pixel circuit PC and the second pixel power line VSL. The light emitting element ED may include a first electrode (e.g., an anode electrode or a pixel electrode), a second electrode (e.g., a cathode electrode or a counter electrode) facing the first electrode, and a light emitting layer interposed between the first electrode and the second electrode. The first electrode of the light emitting element ED may be connected to the second node N2. The second electrode of the light emitting element ED may be connected to the second pixel power line VSL. In an embodiment, the second electrode of the light emitting element ED may be a common electrode shared by the pixels PX. The light emitting element ED may emit light with a luminance corresponding to the driving current Id during a time period in which the driving current Id is supplied from the pixel circuit PC.

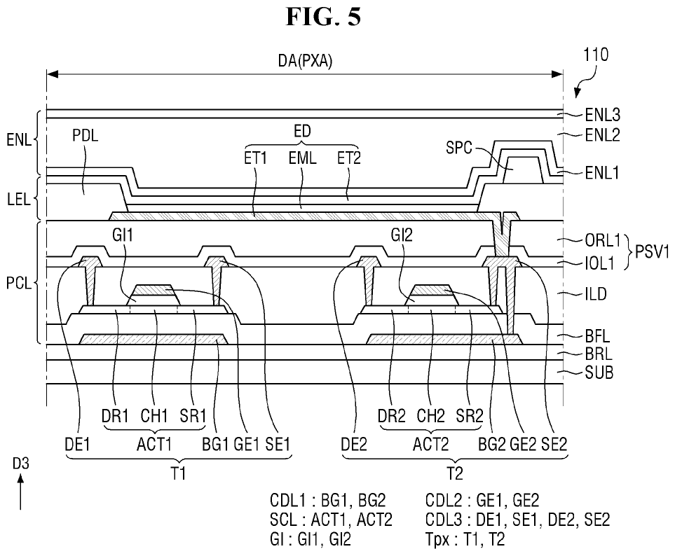

FIG. 4 is a cross-sectional view illustrating the display panel 110, according to an embodiment. FIG. 5 is a cross-sectional view illustrating the display panel 110, according to an embodiment. FIG. 4 illustrates a part of the display area DA of the display panel 110 including a connection electrode CNE and a second passivation layer PSV2, and FIG. 5 illustrates a part of the display area DA of the display panel 110, which does not include the connection electrode CNE and the second passivation layer PSV2.

In an embodiment, FIGS. 4 and 5 illustrate the first transistor T1 and the second transistor T2 disposed in one pixel area PXA as an example of circuit elements that may be provided or disposed in a panel circuit layer PCL of the display panel 110. In addition, FIGS. 4 and 5 show a light emitting display panel including the light emitting element ED (for example, an organic light emitting diode) as an example of the display panel 110 to which embodiments may be applied. However, the type and/or structure of the display panel 110 are not limited thereto. For example, the display panel 110 may include a light emitting element of another type and/or structure, or may be a display panel of another type and/or structure other than the light emitting display panel.

In an embodiment and referring to FIGS. 4 and 5 in addition to FIGS. 1 to 3, the display panel 110 may include the substrate SUB (also referred to as “base member” or “base layer”), the panel circuit layer PCL, a light emitting element layer LEL, and an encapsulation layer ENL. The panel circuit layer PCL, the light emitting element layer LEL, and the encapsulation layer ENL may be disposed or provided to overlap each other on the substrate SUB. For example, with respect to the display area DA, the panel circuit layer PCL, the light emitting element layer LEL, and the encapsulation layer ENL may be sequentially arranged or formed on the substrate SUB along the third direction D3. However, the invention is not limited thereto, and the mutual positions of the panel circuit layer PCL, the light emitting element layer LEL, and the encapsulation layer ENL may be changed. For example, the panel circuit layer PCL and the light emitting element layer LEL may be integrated with each other, or the light emitting element layer LEL may be disposed on top of the panel circuit layer PCL.

In an embodiment, the display panel 110 may further include additional elements provided above and/or under the encapsulation layer ENL. For example, the display panel 110 may further include at least one of a sensor layer (for example, a touch sensor layer), an optical layer (for example, a color filter layer and/or a wavelength conversion layer), or a passivation layer (for example, a passivation film, an insulating layer, an upper substrate, and/or a window). Each of the sensor layer, the optical layer, and/or the passivation layer may be provided above the encapsulation layer ENL or may be provided between the light emitting element layer LEL and the encapsulation layer ENL. In an embodiment, the sensor layer, the optical layer and/or the passivation layer may be provided on the display panel 110. For example, the sensor layer, the optical layer and/or the passivation layer may be integrally manufactured with the display panel 110. In another embodiment, the sensor layer, the optical layer and/or the passivation layer may be manufactured separately from the display panel 110 and attached to the display panel 110 via an adhesive layer or the like.

In an embodiment, the substrate SUB, which is a base member for forming the display panel 110, may be a substrate (or film) having rigid or flexible characteristics. In one embodiment, the substrate SUB may be a substrate including an insulating material such as glass or the like and having rigid characteristics and may not be bent. In another embodiment, the substrate SUB may be a flexible substrate that includes polyimide or another insulating material and may be transformed to be bent, folded, or rolled and may or may not be bent. The type and/or material of the substrate SUB may change depending on embodiments.

In an embodiment, the substrate SUB may include at least the display area DA. In an embodiment, the display area DA may include the pixel areas PXA corresponding to each of the pixels PX. For example, in the display area DA, the respective pixel areas PXA in which each of the pixels PX is disposed may be defined.

In an embodiment, a barrier layer BRL may be provided on the substrate SUB. For example, the display panel 110 may further include the barrier layer BRL disposed between the substrate SUB and the panel circuit layer PCL. In another embodiment, the display panel 110 may not include the barrier layer BRL, and in this case, the panel circuit layer PCL may be disposed directly on the substrate SUB.

In an embodiment, the barrier layer BRL may include at least one inorganic insulating layer containing an inorganic insulating material (e.g., silicon nitride, silicon oxide, silicon oxynitride, titanium oxide, aluminum oxide, or another inorganic insulating material). The barrier layer BRL may protect the pixels PX from moisture permeating through the substrate SUB that is susceptible to moisture permeation. The material of the barrier layer BRL may be variously changed according to embodiments.

In an embodiment, the panel circuit layer PCL may be disposed on one surface of the substrate SUB where the barrier layer BRL is provided. The panel circuit layer PCL may include circuit elements including the pixel transistors Tpx and pixel capacitors (e.g., the capacitor C1 of each of the pixels PX), and wires (e.g., signal lines and power lines). In an embodiment, the panel circuit layer PCL may further include additional conductive patterns (e.g., bridge patterns).

In an embodiment, the panel circuit layer PCL may further include insulating layers disposed on the substrate SUB. For example, the panel circuit layer PCL may include a buffer layer BFL (also referred to as “first insulating layer”), an interlayer insulating layer ILD (also referred to as “second insulating layer”), and a first passivation layer PSV1 (also referred to as “third insulating layer”) sequentially disposed on the substrate SUB along the third direction D3.

In an embodiment, the panel circuit layer PCL may further include the connection electrode CNE and the second passivation layer PSV2 (also referred to as a “fourth insulating layer”) disposed on the first passivation layer PSV1 as illustrated in FIG. 4. In another embodiment, the panel circuit layer PCL may not include the connection electrode CNE and the second passivation layer PSV2 as illustrated in FIG. 5. In the embodiment of FIG. 5, one electrode of the second transistor T2 may be directly connected to one electrode of the light emitting element ED.

In an embodiment, at least one of the first passivation layer PSV1 or the second passivation layer PSV2 may have a multilayer structure including an inorganic layer (e.g., an inorganic insulating layer) and an organic layer (e.g., an organic insulating layer). For example, the first passivation layer PSV1 may include a first inorganic layer IOL1 and a first organic layer ORL1 sequentially disposed on the interlayer insulating layer ILD, and the second passivation layer PSV2 may include a second inorganic layer IOL2 and a second organic layer ORL2 sequentially disposed on the first passivation layer PSV1.

In an embodiment, at least one of the first passivation layer PSV1 or the second passivation layer PSV2 may include at least one inorganic insulating layer including silicon nitride (e.g., SiNₓ). For example, at least one of the first inorganic layer IOL1 or the second inorganic layer IOL2 may include silicon nitride. Accordingly, circuit elements and wires provided in the panel circuit layer PCL may be protected from moisture permeation or the like.

In an embodiment, as illustrated in FIG. 4, when the panel circuit layer PCL includes the first passivation layer PSV1 and the second passivation layer PSV2, the first inorganic layer IOL1 may not include silicon nitride, and the second inorganic layer IOL2 may include silicon nitride. For example, the first inorganic layer IOL1 may include silicon oxide (e.g., SiOₓ), and the second inorganic layer IOL2 may include silicon nitride. Accordingly, the amount of hydrogen introduced into the active layer or the like may be reduced. In an embodiment, as illustrated in FIG. 5, when the panel circuit layer PCL includes the first passivation layer PSV1 and does not include the second passivation layer PSV2, the first inorganic layer IOL1 may include silicon nitride. Accordingly, circuit elements and wires provided in the panel circuit layer PCL may be protected from moisture permeation or the like.

In an embodiment, the panel circuit layer PCL may further include a gate insulating layer GI interposed between the active layer and the gate electrode of each of the pixel transistors Tpx. For example, the panel circuit layer PCL may further include a first gate insulating layer GI1 (also referred to as a “first gate insulating pattern”) interposed between the first active layer ACT1 and the first gate electrode GE1 of the first transistor T1, and a second gate insulating layer GI2 (also referred to as a “second gate insulating pattern”) interposed between the second active layer ACT2 and the second gate electrode GE2 of the second transistor T2.

In an embodiment, FIGS. 4 and 5 illustrate the display panel 110 having a structure in which the first gate insulating layer GI1 and the second gate insulating layer GI2 are etched in island-shaped insulating patterns locally positioned only on portions of the first active layer ACT1 and the second active layer ACT2, respectively. For example, the first gate insulating layer GI1 may be disposed only on a portion of the first active layer ACT1 including a first channel region CH1, and may be an insulating pattern of a shape that exposes a first drain region DR1 and a first source region SR1. As an example, the first gate insulating layer GI1 may have a shape and a size corresponding to those of the first gate electrode GE1. Similarly, the second gate insulating layer GI2 may be disposed only on a portion of the second active layer ACT2 including a second channel region CH2, and may be an insulating pattern of a shape that exposes a second drain region DR2 and a second source region SR2. As an example, the second gate insulating layer GI2 may have a shape and a size corresponding to those of the second gate electrode GE2.

In an embodiment, the shapes of the first gate insulating layer GI1 and the second gate insulating layer GI2 are not limited to the embodiments illustrated in FIGS. 4 and 5. For example, at least one of the first gate insulating layer GI1 or the second gate insulating layer GI2 may be formed entirely in the display area DA. In addition, the first gate insulating layer GI1 and the second gate insulating layer GI2 may be separated from each other, as illustrated in FIGS. 4 and 5, or may be integrated with each other and formed as one gate insulating layer GI.

In an embodiment, each of the buffer layer BFL, the first gate insulating layer GI1, the second gate insulating layer GI2, the interlayer insulating layer ILD, the first inorganic layer IOL1, and the second inorganic layer IOL2 may include at least one inorganic insulating layer containing an inorganic insulating material (e.g., silicon nitride, silicon oxide, silicon oxynitride, titanium oxide, aluminum oxide, or another inorganic insulating material).

In an embodiment, each of the first organic layer ORL1 and the second organic layer ORL2 may include at least one organic insulating layer containing an organic insulating material (e.g., acrylic resin, epoxy resin, phenolic resin, polyamide resin, polyimide resin, or another organic insulating material). The surfaces (e.g., top surfaces) of the first organic layer ORL1 and the second organic layer ORL2 may be substantially flat. The types, materials, shapes and/or structures of the insulating layers and/or insulating patterns provided in the panel circuit layer PCL may be variously changed according to embodiments.

In an embodiment, the pixel transistors Tpx may be included in the pixel circuit PC of each pixel PX, and may be positioned in the display area DA. For example, the first transistor T1 and the second transistor T2 provided to each of the pixels PX may be disposed in each of the pixel areas PXA in which the corresponding pixel PX is positioned. In addition, at least one capacitor (e.g., the capacitor C1 in FIG. 3) provided to the corresponding pixel PX may be further disposed in each of the pixel areas PXA.

In an embodiment, at least one pixel transistor Tpx may include a lower electrode. For example, the first transistor T1 may include a first lower electrode BG1, and the second transistor T2 may include the second lower electrode BG2. In one embodiment, the first lower electrode BG1 and the second lower electrode BG2 may be provided in the same layer (e.g., a first conductive layer CDL1) within the panel circuit layer PCL.

In an embodiment, the first transistor T1 may include the first active layer ACT1 (also referred to as a “first active pattern”) disposed on the substrate SUB and the first gate electrode GE1 disposed on the first active layer ACT1. The first gate electrode GE1 may be disposed on a part of the first active layer ACT1, and the first gate insulating layer GI1 may be disposed between the first gate electrode GE1 and the first active layer ACT1. In one embodiment, the first gate electrode GE1 may be disposed directly on the first gate insulating layer GI1. For example, only the first gate insulating layer GI1 may be interposed between the first gate electrode GE1 and the first active layer ACT1.

In an embodiment, the first transistor T1 may further include the first lower electrode BG1 overlapping the first active layer ACT1. For example, the first transistor T1 may include the first lower electrode BG1 disposed below the first active layer ACT1. In another embodiment, the first transistor T1 may not include the first lower electrode BG1.

In an embodiment, the first transistor T1 may further include a first drain electrode DE1 and a first source electrode SE1 connected to different parts of the first active layer ACT1. In another embodiment, the first transistor T1 may not include a separate drain electrode and/or a separate source electrode, and the first drain region DR1 and/or the first source region SR1 of the first active layer ACT1 may be connected to another circuit element, wire, and/or conductive pattern to function as a drain electrode and/or source electrode of the first transistor T1.

In an embodiment, the first lower electrode BG1 may be provided in the first conductive layer CDL1 on the substrate SUB. In an embodiment, the first conductive layer CDL1 may be disposed between the substrate SUB and the buffer layer BFL. For example, the first conductive layer CDL1 may be disposed on the barrier layer BRL and covered by the buffer layer BFL.

The first lower electrode BG1 may overlap the first active layer ACT1. For example, the first lower electrode BG1 may be disposed under the first active layer ACT1 to overlap at least the first channel region CH1. The buffer layer BFL may be disposed between the first lower electrode BG1 and the first active layer ACT1. The first lower electrode BG1 and the first active layer ACT1 may be spaced apart from each other by a distance corresponding to the thickness of the buffer layer BFL. The first lower electrode BG1 may face the first gate electrode GE1 with the first active layer ACT1 interposed therebetween.

In an embodiment, the first lower electrode BG1 may be connected or may not be connected to one electrode of the first transistor T1. In an embodiment, the first lower electrode BG1 may be connected to the first gate electrode GE1 of the first transistor T1, and may be utilized as a back-gate electrode to adjust the characteristics of the first transistor T1.

In an embodiment, the first active layer ACT1 may be provided in a semiconductor layer SCL on the substrate SUB. In an embodiment, the semiconductor layer SCL may be disposed on the buffer layer BFL, and may be covered by the gate insulating layer GI and the interlayer insulating layer ILD.

In an embodiment, the first active layer ACT1 may include the first channel region CH1 overlapping the first gate electrode GE1, and the first source region SR1 and the first drain region DR1 spaced apart from each other with the first channel region CH1 interposed therebetween. For example, the first source region SR1 and the first drain region DR1 may be located at both sides of the first channel region CH1. The first channel region CH1 may be a region that maintains semiconductor characteristics without becoming conductive, and the first source region SR1 and the first drain region DR1 may be regions that have become conductive.

In an embodiment, the first active layer ACT1 may overlap the first lower electrode BG1 and the first gate electrode GE1. For example, the first channel region CH1 of the first active layer ACT1 may be disposed between the first lower electrode BG1 and the first gate electrode GE1 and may overlap the first lower electrode BG1 and the first gate electrode GE1.

In an embodiment, the first gate electrode GE1 (e.g., the top-gate electrode of the first transistor T1) may be provided in a second conductive layer CDL2 on the substrate SUB. In an embodiment, the second conductive layer CDL2 may be disposed on the semiconductor layer SCL including the first active layer ACT1 and the gate insulating layer GI including the first gate insulating layer GI1. The second conductive layer CDL2 may be covered by the interlayer insulating layer ILD.

In an embodiment, the first gate electrode GE1 may be disposed on the first active layer ACT1 to overlap the first channel region CH1. The first gate electrode GE1 and the first active layer ACT1 may be spaced apart from each other with the first gate insulating layer GI1 interposed therebetween.

In an embodiment, the first gate insulating layer GI1 may be disposed between the first gate electrode GE1 and the first active layer ACT1. The first gate insulating layer GI1 may cover a portion (e.g., the first channel region CH1) of the first active layer ACT1 that overlaps the first gate electrode GE1.

In an embodiment, the first drain electrode DE1 and the first source electrode SE1 may be provided in the third conductive layer CDL3 on the substrate SUB. In an embodiment, the third conductive layer CDL3 may be disposed on the interlayer insulating layer ILD that covers the second conductive layer CDL2 including the first gate electrode GE1.

In an embodiment, the first drain electrode DE1 may be connected to a part of the first active layer ACT1. For example, the first drain electrode DE1 may be connected to the first drain region DR1 through at least one contact hole penetrating the interlayer insulating layer ILD.

In an embodiment, the first source electrode SE1 may be connected to another part of the first active layer ACT1. For example, the first source electrode SE1 may be connected to the first source region SR1 through at least one contact hole penetrating the interlayer insulating layer ILD.

In an embodiment, the second transistor T2 may include the second active layer ACT2 (also referred to as a “second active pattern”) disposed on the substrate SUB and the second gate electrode GE2 disposed on the second active layer ACT2. The second gate electrode GE2 may be disposed on a part of the second active layer ACT2, and the second gate insulating layer GI2 may be disposed between the second gate electrode GE2 and the second active layer ACT2. In an embodiment, the second gate electrode GE2 may be disposed directly on the second gate insulating layer GI2. For example, only the second gate insulating layer GI2 may be interposed between the second gate electrode GE2 and the second active layer ACT2.

In an embodiment, the second transistor T2 may further include the second lower electrode BG2 overlapping the second active layer ACT2. For example, the second transistor T2 may include the second lower electrode BG2 disposed below the second active layer ACT2. In another embodiment, the second transistor T2 may not include the second lower electrode BG2.

In an embodiment, the second transistor T2 may further include a second drain electrode DE2 and a second source electrode SE2 connected to different parts of the second active layer ACT2. In another embodiment, the second transistor T2 may not include a separate drain electrode and/or a separate source electrode, and the second drain region DR2 and/or the second source region SR2 of the second active layer ACT2 may be connected to another circuit element, wire, and/or conductive pattern to function as a drain electrode and/or source electrode of the second transistor T2.

In an embodiment, the second lower electrode BG2 may be provided in the first conductive layer CDL1 on the substrate SUB. For example, the second lower electrode BG2 may be provided in the second conductive layer CDL2 together with the first lower electrode BG1.

In an embodiment, the second lower electrode BG2 may overlap the second active layer ACT2. For example, the second lower electrode BG2 may be disposed under the second active layer ACT2 to overlap at least the second channel region CH2. The buffer layer BFL may be interposed between the second lower electrode BG2 and the second active layer ACT2. The second lower electrode BG2 and the second active layer ACT2 may be spaced apart from each other by a distance corresponding to the thickness of the buffer layer BFL. The second lower electrode BG2 may face the second gate electrode GE2 with the second active layer ACT2 interposed therebetween.

In an embodiment, the second lower electrode BG2 may be connected or may not be connected to one electrode of the second transistor T2. In an embodiment, the second lower electrode BG2 may be connected to the second source electrode SE2 of the second transistor T2 and may be utilized as a back-gate electrode to adjust the characteristics of the second transistor T2.

In an embodiment, the second active layer ACT2 may be provided in the semiconductor layer SCL on the substrate SUB. In an embodiment, the first active layer ACT1 and the second active layer ACT2 may be provided and/or disposed in the same layer (e.g., the same semiconductor layer SCL) on the substrate SUB and may include the same oxide semiconductor.

In an embodiment, the second active layer ACT2 may include a second channel region CH2 overlapping the second gate electrode GE2, and a second source region SR2 and a second drain region DR2 spaced apart from each other with the second channel region CH2 interposed therebetween. For example, the second source region SR2 and the second drain region DR2 may be located at both sides of the second channel region CH2. The second channel region CH2 may be a region that maintains semiconductor characteristics without becoming conductive, and the second source region SR2 and the second drain region DR2 may be regions that have become conductive.

In an embodiment, the second active layer ACT2 may overlap the second lower electrode BG2 and the second gate electrode GE2. For example, the second channel region CH2 of the second active layer ACT2 may overlap the second lower electrode BG2 and the second gate electrode GE2.

In an embodiment, the second gate electrode GE2 (e.g., the top-gate electrode of the second transistor T2) may be provided in the second conductive layer CDL2 on the substrate SUB. In an embodiment, the first gate electrode GE1 and the second gate electrode GE2 may be provided and/or disposed in the same layer (e.g., the same second conductive layer CDL2) on the substrate SUB. For example, the second gate electrode GE2 may be disposed between the gate insulating layer GI including the first and second gate insulating layers GI1 and GI2 and the interlayer insulating layer ILD.

In an embodiment, the second gate electrode GE2 may be disposed on the second active layer ACT2 to overlap the second channel region CH2. The second gate electrode GE2 and the second active layer ACT2 may be spaced apart from each other with the second gate insulating layer GI2 interposed therebetween.

In an embodiment, the second gate insulating layer GI2 may be disposed between the second gate electrode GE2 and the second active layer ACT2. The second gate insulating layer GI2 may cover a portion (e.g., the second channel region CH2) of the second active layer ACT2 that overlaps the second gate electrode GE2. In an embodiment, the first gate insulating layer GI1 and the second gate insulating layer GI2 may be provided and/or disposed in the same layer (e.g., the gate insulating layer GI between the semiconductor layer SCL and the second conductive layer CDL2) on the substrate SUB and may include the same insulating material.

In an embodiment, the second drain electrode DE2 and the second source electrode SE2 may be provided in the third conductive layer CDL3 on the substrate SUB. In an embodiment, the second drain electrode DE2 and the second source electrode SE2 may be disposed in the same layer as the first drain electrode DE1 and the first source electrode SE1 on the substrate SUB. For example, the second drain electrode DE2 and the second source electrode SE2 may be disposed on the interlayer insulating layer ILD covering the second conductive layer CDL2 including the first gate electrode GE1 and the second gate electrode GE2, and may be covered by the first passivation layer PSV1.

In an embodiment, the second drain electrode DE2 may be connected to a part of the second active layer ACT2. For example, the second drain electrode DE2 may be connected to the second drain region DR2 through at least one contact hole penetrating the interlayer insulating layer ILD.

In an embodiment, the second source electrode SE2 may be connected to another part of the second active layer ACT2. For example, the second source electrode SE2 may be connected to the second source region SR2 through at least one contact hole penetrating the interlayer insulating layer ILD. In an embodiment, the second source electrode SE2 may be further connected to the second lower electrode BG2. For example, the second source electrode SE2 may be connected to the second lower electrode BG2 through at least one contact hole penetrating the buffer layer BFL and the interlayer insulating layer ILD.

In an embodiment, the pixel transistors Tpx, including the first transistor T1 and the second transistor T2 may be covered by at least one passivation layer. For example, the pixel transistors Tpx may be covered by the first passivation layer PSV1 and the second passivation layer PSV2 as illustrated in FIG. 4 or may be covered by the first passivation layer PSV1 as illustrated in FIG. 5.

In the embodiment of FIG. 4, the second transistor T2 of each of the pixels PX may be connected to the light emitting element ED of the corresponding pixel PX through the connection electrode CNE. The connection electrode CNE may be provided in a fourth conductive layer CDL4 on the substrate SUB. In an embodiment, the fourth conductive layer CDL4 may be disposed on the first passivation layer PSV1 and may be covered by the second passivation layer PSV2. For example, the fourth conductive layer CDL4 may be disposed between the first passivation layer PSV1 and the second passivation layer PSV2. When the display panel 110 further includes the fourth conductive layer CDL4, the number of conductive layers provided in the display panel 110 increases. Accordingly, sufficient design space for forming various conductive patterns (e.g., electrodes and/or bridge patterns), wires, or the like within the display panel 110 may be secured. Accordingly, even when the display panel 110 is formed at high resolution, the pixel circuits PC and wires may be easily and/or appropriately formed.

In an embodiment, the connection electrode CNE may be connected to one electrode of the second transistor T2. As an example, the connection electrode CNE may be disposed on the second source electrode SE2 and may be connected to the second source electrode SE2 through at least one contact hole or via hole penetrating the first passivation layer PSV1.

In an embodiment of FIG. 5, the second transistor T2 of each of the pixels PX may be connected to the light emitting element ED of the corresponding pixel PX without going through the connection electrode CNE. For example, the second source electrode SE2 of each of the pixels PX may be directly connected to the light emitting element ED of the corresponding pixel PX.

In an embodiment, the respective electrodes, conductive patterns, and/or wires provided on the conductive layers of the panel circuit layer PCL may include at least one conductive material, and may each have a single layer structure or a multilayer structure. For example, the electrodes, the conductive patterns, and/or the wires provided on each of the first conductive layer CDL1, the second conductive layer CDL2, the third conductive layer CDL3, and the fourth conductive layer CDL4 may include at least one of copper (Cu), titanium (Ti), molybdenum (Mo), aluminum (Al), chromium (Cr), gold (Au), silver (Ag), platinum (Pt), palladium (Pd), nickel (Ni), neodymium (Nd), iridium (Ir), tantalum (Ta), tungsten (W), magnesium (Mg), or another metal, an alloy thereof, or another conductive material, and may each have a single layer structure or a multilayer structure. In an embodiment, the electrodes, the conductive patterns, and/or the wires disposed on the same conductive layer may be simultaneously formed using the same conductive material.

In an embodiment, at least one active layer provided in the semiconductor layer SCL may include an oxide semiconductor containing indium (In). For example, each of the first active layer ACT1 and the second active layer ACT2 may include an oxide semiconductor containing indium (In) at a content range of about 40 at % (atomic percent) to about 54 at %.

In an embodiment, by controlling the atomic ratio of indium (In) contained in the active layer within the range exemplified above, the carrier concentration and/or conductivity of the active layer may be appropriately controlled, and the element characteristics (e.g., mobility and threshold voltage) of the transistor may be appropriately controlled and/or secured. For example, by limiting the atomic ratio of indium (In) contained in each of the first active layer ACT1 and the second active layer ACT2 to a range of about 40 at % to about 54 at %, the characteristics of the first transistor T1 and the second transistor T2 may be controlled such that each of the first transistor T1 and the second transistor T2 has a mobility (e.g., electron mobility in the range of about 20 cm²/Vs to about 50 cm²/Vs) and a threshold voltage (e.g., a threshold voltage in the range of about −1.0 V to about +0.5 V) appropriate for driving the pixel PX. The mobility and threshold voltage of the first transistor T1 and the second transistor T2 are not limited to the ranges exemplified above and may vary depending on the design conditions or driving conditions of the display panel 110.

In an embodiment, at least one active layer provided in the semiconductor layer SCL may further contain at least one of gallium (Ga), zinc (Zn), or tin (Sn). For example, each of the first active layer ACT1 and the second active layer ACT2 may contain indium (In) at a content range of about 40 at % to about 54 at %, and may include an oxide semiconductor further containing at least one of gallium (Ga), zinc (Zn), or tin (Sn). As an example, each of the first active layer ACT1 and the second active layer ACT2 may be made of a high-mobility oxide semiconductor (e.g., an oxide semiconductor material having a mobility of approximately 20 cm²/Vs or more or about 30 cm²/Vs or more) including indium-gallium-zinc oxide (IGZO), indium-tin-gallium oxide (ITGO), or indium-tin-gallium-zinc oxide (ITGZO). However, the materials of the first active layer ACT1 and the second active layer ACT2 are not limited to the materials exemplified above. For example, each of the first active layer ACT1 and the second active layer ACT2 may be made of indium-gallium oxide (IGO), indium-zinc oxide (IZO), or another oxide semiconductor.

In an embodiment, in the case that the first active layer ACT1 and the second active layer ACT2 are formed of a high-mobility oxide semiconductor, the mobility of the first transistor T1 and the second transistor T2 may be appropriately secured while the first transistor T1 and the second transistor T2 are formed in a fine size (e.g., a size including an active layer with a width and/or length in the range of approximately several micrometers to several tens of micrometers). Accordingly, even in a high-resolution display device in which the area of the pixel area PXA is relatively small, the pixel transistors Tpx may be easily disposed and/or formed, and the element characteristics and/or operating characteristics of the pixel transistors Tpx may be appropriately secured. In addition, by forming the first active layer ACT1 and the second active layer ACT2 with a high-mobility oxide semiconductor, the power consumption of the display device 100 may be reduced.

In an embodiment, at least one gate insulating layer GI may have an emission amount range of nitrogen monoxide (NO) of about 1.04E+20 Molec./cm³ to about 1.15E+20 Molec./cm³ (e.g., an emission amount range of nitrogen monoxide (NO) is about 1.04*10²⁰ Molec./cm³ or more and about 1.15*10²⁰ Molec./cm³ or less), and/or an emission amount range of oxygen (O₂) of about 2.48E+19 Molec./cm³ to about 2.76E+19 Molec./cm³ (e.g., an emission amount range of oxygen (O₂) is about 2.48*10¹⁹ Molec./cm³ or more and about 2.76*10¹⁹ Molec./cm³ or less). For example, in the analysis by thermal desorption spectroscopy (TDS) (or elevated temperature escape gas spectroscopy using heat treatment) using heat treatment (e.g., heat treatment performed at a surface temperature in the range of about 50° C. to about 550° C.), at least one gate insulating layer GI may be an insulating layer (or insulating pattern) in which an emission amount range of nitrogen monoxide (NO) in a case of conversion to nitrogen monoxide (NO) is about 1.04E+20 Molec./cm³ to about 1.15E+20 Molec./cm³, or an emission amount range of oxygen (O₂) in a case of conversion to oxygen (O₂) is about 2.48E+19 Molec./cm³ to about 2.76E+19 Molec./cm³.

In an embodiment, each of the first gate insulating layer GI1 and the second gate insulating layer GI2 may be an insulating layer (or insulating pattern) with an emission amount range of nitrogen monoxide (NO) of about 1.04E+20 Molec./cm³ to about 1.15E+20 Molec./cm³, and/or an emission amount range of oxygen (O₂) of about 2.48E+19 Molec./cm³ to about 2.76E+19 Molec./cm³. For example, each of the first gate insulating layer GI1 and the second gate insulating layer GI2 may include silicon oxide (e.g., SiOₓ) and may be an insulating layer that emits nitrogen monoxide (NO) and/or oxygen (O₂) at a concentration within the range exemplified above through a heat treatment process or the like. As an example, in the heat treatment process (e.g., the heat treatment process or the like of the gate insulating layer GI and/or the interlayer insulating layer ILD performed at a temperature in the range of approximately 50° C. to about 550° C.) subsequent to the deposition of the gate insulating layer GI including the first gate insulating layer GI1 and the second gate insulating layer GI2, the first gate insulating layer GI1 and the second gate insulating layer GI2 may emit nitrogen monoxide (NO) within the concentration range of about 1.04E+20 Molec./cm³ to about 1.15E+20 Molec./cm³, or may emit oxygen (O₂) within the concentration range of about 2.48E+19 Molec./cm³ to about 2.76E+19 Molec./cm³. Depending on the concentration of nitrogen monoxide (NO) and/or oxygen (O₂) emitted from the first gate insulating layer GI1 and the second gate insulating layer GI2, element characteristics (e.g., carrier concentration) of the first active layer ACT1 and the second active layer ACT2 may be changed. Accordingly, by appropriately controlling the concentration of nitrogen monoxide (NO) and/or oxygen (O₂) emitted from the first gate insulating layer GI1 and the second gate insulating layer GI2, the electrical characteristics of the first transistor T1 and the second transistor T2 may be stabilized.

In addition, in an embodiment, the amount of nitrogen monoxide (NO) and/or oxygen (O₂) emitted from each of the gate insulating layers GI may be controlled in addition to the content of indium (In) contained in each active layer. Accordingly, the electrical characteristics of the first transistor T1 and the second transistor T2 may be optimized and/or stabilized. For example, although the first active layer ACT1 and the second active layer ACT2 are formed using a high-mobility oxide semiconductor, oxygen may be supplied to the first active layer ACT1 and the second active layer ACT2 in a subsequent process including heat treatment. Accordingly, without forming a separate oxygen supply layer or the like on the first active layer ACT1 and the second active layer ACT2 including a high-mobility oxide semiconductor (e.g., on the gate insulating layer GI), the carrier concentration of the first active layer ACT1 and the second active layer ACT2 may be appropriately and/or easily controlled.

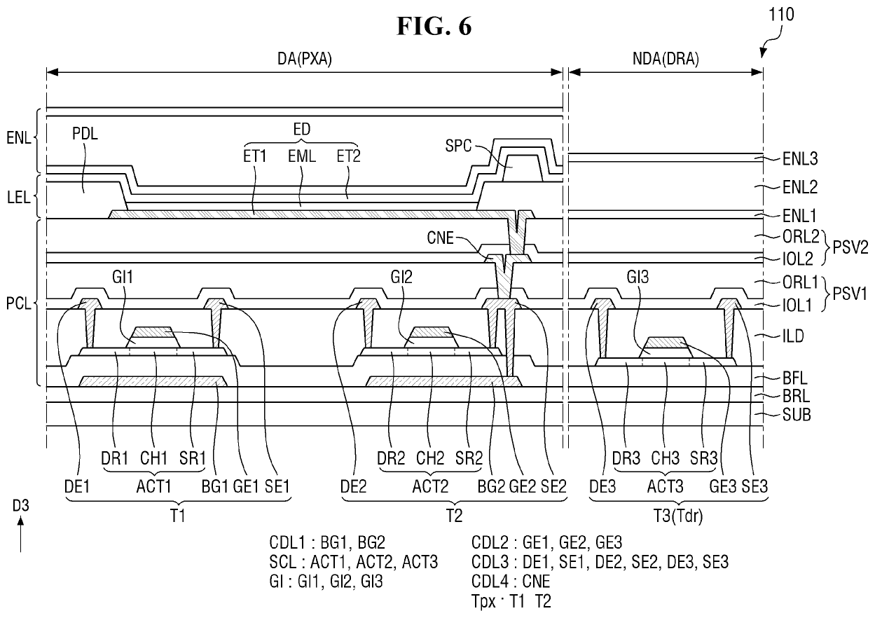

In an embodiment, in addition to the content of indium (In) contained in each active layer, the amount of nitrogen monoxide (NO) and/or oxygen (O₂) emitted from the gate insulating layer GI may be controlled to the exemplified range, so that the first active layer ACT1 and the second active layer ACT2 may be formed such that the first transistor T1 and the second transistor T2 have element characteristics (or operating characteristics) suitable for the switching transistor and driving transistor of the pixel PX. In an embodiment, the content of indium (In) of the active layer exemplified above and the gas emission amount (e.g., an emission amount of nitrogen monoxide (NO) or oxygen (O₂)) of the gate insulating layer GI may be values suitable (or optimized) for forming the pixel transistors Tpx to satisfy all element characteristics (e.g., the threshold voltage and mobility in an appropriate range required for the switching transistor in particular) required for the switching transistor (e.g., the first transistor T1) and the driving transistor (e.g., the second transistor T2) of the pixel PX. Additionally, the content of indium (In) of the active layer exemplified above and the gas emission amount of the gate insulating layer GI may also be values suitable for forming driver transistors to satisfy the element characteristics (or operating characteristics) required by the driver transistors (e.g., a third transistor T3 in FIG. 6) provided in the first driver 120 or the like.

According to an embodiment, the element characteristics of each transistor may be appropriately controlled without forming a separate oxygen supply layer or the like in and/or around the transistor. Accordingly, the structure and manufacturing process of the display panel 110 may be simplified and/or streamlined, and the manufacturing efficiency of the display panel 110 may be increased.

In an embodiment, the light emitting element layer LEL may be disposed on the panel circuit layer PCL, and may be located in the display area DA. For example, the light emitting element layer LEL may be disposed on the panel circuit layer PCL in the display area DA.

In an embodiment, the light emitting element layer LEL may include the light emitting elements ED of the pixels PX. For example, the light emitting element layer LEL may include a pixel defining layer PDL (also referred to as “bank”) that partitions the emission areas of the pixels PX and the light emitting element ED located in each emission area. In an embodiment, the light emitting element layer LEL may further include a spacer SPC disposed on a part of the pixel defining layer PDL.

In an embodiment, each light emitting element ED may include the first electrode ET1 (for example, an anode electrode) connected to at least one pixel transistor Tpx (for example, the second pixel transistor T2) included in the corresponding pixel PX, and a light emitting layer EML and a second electrode ET2 (for example, a cathode electrode) that are sequentially disposed on the first electrode ET1. In an embodiment, the light emitting element ED may further include a first intermediate layer (e.g., hole layer including a hole transport layer) interposed between the first electrode ET1 and the light emitting layer EML, and a second intermediate layer (e.g., an electron layer including an electron transport layer) interposed between the light emitting layer EML and the second electrode ET2.

In an embodiment, the first electrode ET1 of the light emitting element ED may be disposed on the panel circuit layer PCL. In the embodiment of FIG. 4, the first electrode ET1 may be disposed on the second passivation layer PSV2 to correspond to each emission area and may be connected to the connection electrode CNE through at least one contact hole or via hole penetrating the second passivation layer PSV2. In the embodiment of FIG. 5, the first electrode ET1 may be disposed on the first passivation layer PSV1 to correspond to each emission area and may be directly connected to at least one pixel transistor Tpx.

In an embodiment, the first electrode ET1 may include a conductive material. In an embodiment, the first electrode ET1 may include a metallic material having high reflectivity. For example, the first electrode ET1 may have a single-layer structure of molybdenum (Mo), titanium (Ti), copper (Cu) or aluminum (Al), or may have a multi-layer structure (e.g., ITO/Mg, ITO/MgF, ITO/Ag, and ITO/Ag/ITO) including indium-tin-oxide (ITO), indium-zinc-oxide (IZO), zinc oxide (ZnO), indium oxide (In₂O₃) and silver (Ag), magnesium (Mg), aluminum (Al), platinum (Pt), lead (Pb), gold (Au), or nickel (Ni).

In an embodiment, the light emitting layer EML of the light emitting element ED may include a high molecular material or a low molecular material. Light emitted from the light emitting layer EML may contribute to image display. In an embodiment, the light emitting layer EML may be provided for each pixel PX, and the light emitting layer EML of each pixel PX may emit visible light of a color corresponding to the corresponding pixel PX. In another embodiment, the light emitting layer EML may be a common layer shared by pixels PX of different colors, and a wavelength conversion layer and/or color filters corresponding to the color (or wavelength band) of light desired to be emitted from each pixel PX may be arranged in the emission areas of at least some of the pixels PX.

In an embodiment, the second electrode ET2 of the light emitting element ED may include a conductive material. In an embodiment, the second electrode ET2 may be a common layer formed across the entire display area DA to cover the light emitting layer EML and the pixel defining layer PDL. In an embodiment, the second electrode ET2 may be formed of a transparent conductive material (TCO) such as ITO, IZO, ZnO, or ITZO capable of transmitting light or a semi-transmissive conductive material such as magnesium (Mg), silver (Ag), or an alloy of magnesium (Mg) and silver (Ag).

In an embodiment, the pixel defining layer PDL may have an opening corresponding to each emission area and may surround the emission area. For example, the pixel defining layer PDL may be formed to cover an edge of the first electrode ET1 of the light emitting element ED and may include an opening exposing the remaining portion of the first electrode ET1. A region where the exposed first electrode ET1 and the light emitting layer EML overlap (or a region including the same) may be defined as the emission area of each pixel PX.

In an embodiment, the pixel defining layer PDL may include at least one organic insulating layer containing an organic insulating material. For example, the pixel defining layer PDL may include acrylic resin, epoxy resin, phenolic resin, polyamide resin, polyimide resin, unsaturated polyester resin, polyphenylene ether resin, polyphenylenesulfide resin and benzocyclobutene (BCB) or other organic insulating materials.

In an embodiment, the spacer SPC may be disposed on a part of the pixel defining layer PDL. The spacer SPC may include at least one organic insulating layer containing an organic insulating material. The spacer SPC may include the same material as the pixel defining layer PDL or may include a different material from the pixel defining layer PDL. In an embodiment, the pixel defining layer PDL and the spacer SPC may be sequentially formed through separate mask processes. In another embodiment, the pixel defining layer PDL and the spacer SPC may be simultaneously formed using a halftone mask. In this case, the pixel defining layer PDL and the spacer SPC may be regarded as a single insulating layer that is integral with each other.

In an embodiment, the encapsulation layer ENL may be disposed on the light emitting element layer LEL. The encapsulation layer ENL may cover the light emitting element layer LEL in the display area DA and may extend to the non-display area NDA to be in contact with the panel circuit layer PCL. For example, the encapsulation layer ENL may be disposed in the display area DA to cover the light emitting element layer LEL, and the end of the encapsulation layer ENL may be located in a portion of the non-display area NDA adjacent to the display area DA. The encapsulation layer ENL may block the permeation of oxygen or moisture into the light emitting element layer LEL and may reduce electrical and/or physical impacts to the panel circuit layer PCL and the light emitting element layer LEL.

In an embodiment, the encapsulation layer ENL may have a multilayer structure including a first encapsulation layer ENL1, a second encapsulation layer ENL2, and a third encapsulation layer ENL3 sequentially disposed on the light emitting element layer LEL. Each of the first encapsulation layer ENL1 and the third encapsulation layer ENL3 may be an inorganic encapsulation layer containing an inorganic material. The second encapsulation layer ENL2 may be an organic encapsulation layer containing an organic material. The structure and/or material of the encapsulation layer ENL may be changed according to embodiments.

FIG. 6 is a cross-sectional view illustrating the display panel 110, according to an embodiment. For example, FIG. 6 illustrates a part of the display area DA and a part of the non-display area NDA of the display panel 110. FIG. 6 illustrates the first transistor T1 and the second transistor T2 according to the embodiment of FIG. 4 as an example of circuit elements that may be provided or disposed in the display area DA of the panel circuit layer PCL and illustrates one driver transistor Tdr provided or disposed in a driving circuit area DRA as an example of additional circuit elements that may be provided to the panel circuit layer PCL.

In an embodiment and referring to FIG. 6 in addition to FIGS. 1 to 5, the display panel 110 may further include the driver transistors Tdr provided in the driving circuit area DRA. For example, the display panel 110 may be provided in the driving circuit area DRA corresponding to a part of the non-display area NDA and may further include a plurality of driver transistors Tdr provided in the stage circuits constituting the first driver 120. In FIG. 6, only one driver transistor Tdr is illustrated to represent the driver transistors Tdr, and this will be referred to as the “third transistor T3.”

In an embodiment, the substrate SUB and the display panel 110 including the same may include the display area DA and the non-display area NDA. In an embodiment, the non-display area NDA may include the driving circuit area DRA. For example, the driving circuit area DRA in which the first driver 120 is disposed may be defined in the non-display area NDA.

In an embodiment, the panel circuit layer PCL may further include the driver transistors Tdr including the third transistor T3 in addition to the pixel transistors Tpx. The driver transistors Tdr may be provided in stage areas (e.g., respective stage areas in which stage circuits of the shift register constituting the first driver 120 are provided) positioned in the driving circuit area DRA.

In an embodiment, at least one driver transistor Tdr may not include a lower electrode. For example, the driver transistors Tdr including the third transistor T3 may not include a lower electrode. However, the invention is not limited thereto. For example, a lower electrode provided to the first conductive layer CDL1 may be disposed under the active layer (e.g., a third active layer ACT3) of at least one driver transistor Tdr. In an embodiment, a lower electrode provided to at least one driver transistor Tdr may be connected to one electrode (e.g., gate electrode) of the corresponding driver transistor Tdr.

In an embodiment, the third transistor T3 may include the third active layer ACT3 (also referred to as a “third active pattern”) disposed on the substrate SUB and a third gate electrode GE3 disposed on the third active layer ACT3. The third gate electrode GE3 may be disposed on a part of the third active layer ACT3, and a third gate insulating layer GI3 may be disposed between the third gate electrode GE3 and the third active layer ACT3.

In an embodiment, the third transistor T3 may further include a third drain electrode DE3 and a third source electrode SE3 connected to different parts of the third active layer ACT3. In another embodiment, the third transistor T3 may not include a separate drain electrode and/or a separate source electrode, and the third drain region DR3 and/or the third source region SR3 of the third active layer ACT3 may be connected to another circuit element, wire, and/or conductive pattern to function as a drain electrode and/or source electrode of the third transistor T3.

In an embodiment, the third active layer ACT3 may be provided on the semiconductor layer SCL on the substrate SUB. In an embodiment, the first active layer ACT1, the second active layer ACT2, and the third active layer ACT3 may be provided and/or disposed in the same layer (e.g., the same semiconductor layer SCL) on the substrate SUB.

In an embodiment, the third active layer ACT3 may include the same oxide semiconductor as the first active layer ACT1 and/or the second active layer ACT2 and may be formed simultaneously with the first active layer ACT1 and/or the second active layer ACT2. For example, the first active layer ACT1, the second active layer ACT2, and the third active layer ACT3 may include the same oxide semiconductor. For example, the third active layer ACT3 may include an oxide semiconductor containing indium (In) at a content range of about 40 at % to about 54 at %.

In an embodiment, the third active layer ACT3 may include the third channel region CH3, and the third source region SR3 and the third drain region DR3 that are spaced apart from each other with the third channel region CH3 interposed therebetween. For example, the third source region SR3 and the third drain region DR3 may be located on either side of the third channel region CH3. The third channel region CH3 may be a region that maintains semiconductor characteristics without becoming conductive, while the third source region SR3 and the third drain region DR3 may be regions that have become conductive.

In an embodiment, the third active layer ACT3 may overlap the third gate electrode GE3. For example, a part of the third active layer ACT3 including the third channel region CH3 may overlap the third gate electrode GE3.

In an embodiment, the third gate electrode GE3 (e.g., the top-gate electrode of the third transistor T3) may be provided in the second conductive layer CDL2 on the substrate SUB. In an embodiment, the first gate electrode GE1, the second gate electrode GE2, and the third gate electrode GE3 may be provided and/or disposed in the same layer (e.g., the same second conductive layer CDL2) on the substrate SUB, and may be formed simultaneously.

In an embodiment, the third gate electrode GE3 may be disposed on the third active layer ACT3 to overlap the third channel region CH3. The third gate electrode GE3 and the third active layer ACT3 may be spaced apart from each other with the third gate insulating layer GI3 interposed therebetween.

In an embodiment, the third gate insulating layer GI3 may be disposed between the third gate electrode GE3 and the third active layer ACT3. The third gate insulating layer GI3 may cover a portion (e.g., the third channel region CH3) of the third active layer ACT3 that overlaps the third gate electrode GE3.

In an embodiment, the third gate insulating layer GI3 may include the same material as the first gate insulating layer GI1 and/or the second gate insulating layer GI2 and may be formed simultaneously with the first gate insulating layer GI1 and/or the second gate insulating layer GI2. For example, the first gate insulating layer GI1, the second gate insulating layer GI2, and the third gate insulating layer GI3 may include the same insulating material (e.g., silicon oxide), and may be formed to substantially have the same or similar film quality. For example, the third gate insulating layer GI3 may be formed as an insulating layer (or insulating pattern) with an emission amount range of nitrogen monoxide (NO) of about 1.04E+20 Molec./cm³ to about 1.15E+20 Molec./cm³ or an emission amount range of oxygen (O₂) of about 2.48E+19 Molec./cm³ to about 2.76E+19 Molec./cm³.

In an embodiment, the third drain electrode DE3 and the third source electrode SE3 may be provided in the third conductive layer CDL3 on the substrate SUB. In an embodiment, the third drain electrode DE3 and the third source electrode SE3 may be disposed in the same layer as the first and second drain electrodes DE1 and DE2 and the first and second source electrodes SE1 and SE2 on the substrate SUB. For example, the third drain electrode DE3 and the third source electrode SE3 may be disposed on the interlayer insulating layer ILD covering the second conductive layer CDL2 and may be covered by the first passivation layer PSV1.

In an embodiment, the third drain electrode DE3 may be connected to a part of the third active layer ACT3. For example, the third drain electrode DE3 may be connected to the third drain region DR3 through at least one contact hole penetrating the interlayer insulating layer ILD.

In an embodiment, the third source electrode SE3 may be connected to another part of the third active layer ACT3. For example, the third source electrode SE3 may be connected to the third source region SR3 through at least one contact hole penetrating the interlayer insulating layer ILD.

In an embodiment, the pixel transistors Tpx including the first transistor T1 and the second transistor T2 and the driver transistors Tdr including the third transistor T3 may be covered by at least the first passivation layer PSV1. For example, the pixel transistors Tpx and the driver transistors Tdr may be covered by the first passivation layer PSV1 and the second passivation layer PSV2 as illustrated in FIG. 4 or may be covered by the first passivation layer PSV1 as illustrated in FIG. 5.

In an embodiment, the content of indium (In) contained in the third active layer ACT3 may be controlled at a range of about 40 at % to about 54 at %, and at the same time, the amount of nitrogen monoxide (NO) and/or oxygen (O₂) emitted from the third gate insulating layer GI3 may be controlled to the exemplified range (e.g., an emission amount range of nitrogen monoxide (NO) is about 1.04E+20 Molec./cm³ to about 1.15E+20 Molec./cm³, and/or an emission amount range of oxygen (O₂) is about 2.48E+19 Molec./cm³ to about 2.76E+19 Molec./cm³). Accordingly, the third transistor T3 may have element characteristics (or operating characteristics) suitable for a switching transistor or a pull-up or pull-down transistor of the first driver 120.

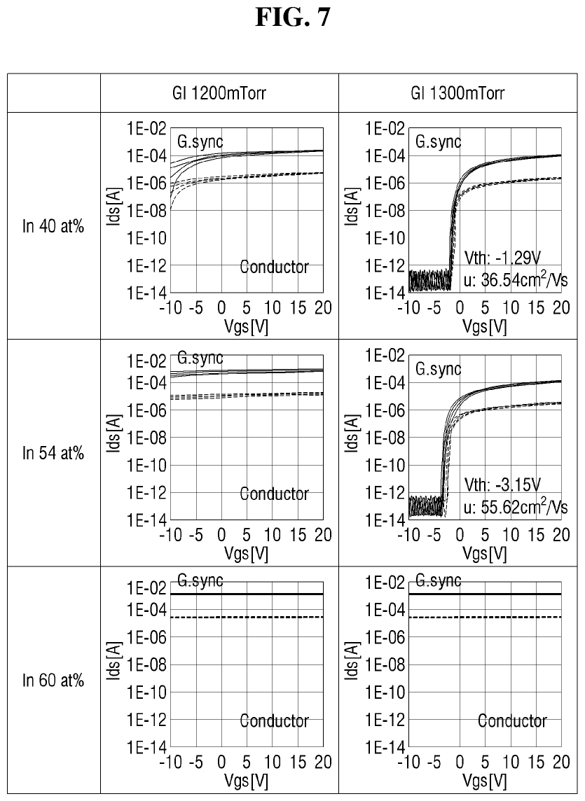

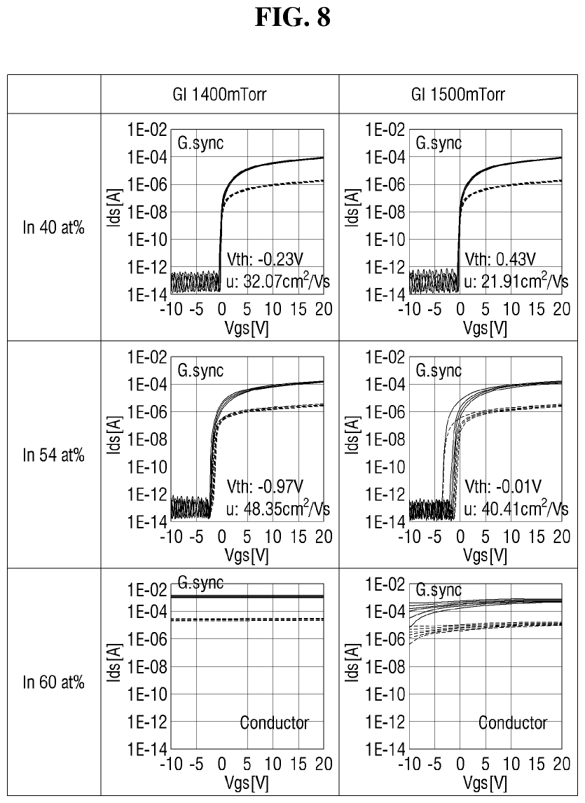

In an embodiment, FIGS. 7 and 8 illustrate changes in the characteristics of the transistor depending on the content of indium (In) contained in the active layer of the transistor and the deposition pressure of the gate insulating layer GI. For example, FIG. 7 illustrates the electrical characteristics exhibited by the transistor through a drain-source current Ids according to the gate-source voltage Vgs in case that the gate insulating layer GI is deposited at a pressure of each of about 1200 mTorr (millitorr) and about 1300 mTorr on the active layers with the contents of indium (In) of about 40 at %, about 54 at %, and about 60 at %, respectively. FIG. 8 illustrates the electrical characteristics exhibited by the transistor through a drain-source current Ids according to the gate-source voltage Vgs in case that the gate insulating layer GI is deposited at a pressure of each of about 1400 mTorr and about 1500 mTorr on the active layers with the contents of indium (In) of about 40 at %, about 54 at %, and about 60 at %, respectively. FIGS. 7 and 8 illustrate the electrical characteristics exhibited by the transistor when the gate insulating layer GI is deposited at a pressure of each of about 1200 mTorr, about 1300 mTorr, about 1400 mTorr, and about 1500 mTorr on the active layers made of indium-gallium-zinc oxide (IGZO) with the contents of indium (In) of about 40 at %, about 54 at %, and about 60 at %, respectively (or indium-tin-gallium-zinc oxide (ITGZO) added with a small amount (e.g., approximately 1 at % to about 2 at %) of tin (Sn) and the contents of indium (In) or the contents of indium (In) and tin (Sn) of about 40 at %, about 54 at %, and about 60 at %, respectively).

In an embodiment and referring to FIGS. 7 and 8, a transistor with a channel width of about 9.5 μm and a channel length of about 6.0 μm in the active layer is formed in a gate-sink structure (e.g., a double gate structure in which the lower electrode is connected to the gate electrode), and the results of measuring electrical characteristics of the transistor are illustrated. In addition, the solid line graph and the dotted line graph represent the results of measuring the electrical characteristics of the transistor under different drain-source voltage Vds conditions. For example, the solid line graph and the dotted line graph represent measurement results when the drain-source voltage Vds is about 5.1 V and about 0.1 V, respectively, and a threshold voltage Vth is a value extracted from the measured value when the drain-source voltage Vds is about 5.1 V. The thickness of the gate insulating layer GI interposed between the active layer of the transistor and the gate electrode may be approximately 1400 Å.

In an embodiment and referring to FIG. 7 in addition to FIGS. 1 to 6, when the deposition pressure of the gate insulating layer GI is lower than about 1400 mTorr, for example, when the gate insulating layer GI is deposited at a pressure of about 1200 mTorr or about 1300 mTorr, the transistor may exhibit electrical characteristics that are unsuitable for use as the pixel transistor Tpx and/or the driver transistor Tdr. For example, when the deposition pressure of the gate insulating layer GI is about 1200 mTorr, the transistor may exhibit substantially the same operating characteristics as a conductor. Although the deposition pressure of the gate insulating layer GI is about 1300 mTorr and the content of indium (In) of the active layer is about 60 at %, the transistor may exhibit substantially the same operating characteristics as a conductor. When the deposition pressure of the gate insulating layer GI is about 1300 mTorr and the content of indium (In) of the active layer is about 40 at % or about 54 at %, the transistor may not exhibit the same operating characteristics as a conductor, but may exhibit electrical characteristics that are unsuitable for use as the pixel transistor Tpx and/or the driver transistor Tdr of the display panel 110 because a negative shift value of the threshold voltage Vth is large.

In an embodiment and referring to FIG. 8 in addition to FIGS. 1 to 7, when the deposition pressure range of the gate insulating layer GI is about 1400 mTorr or more to about 1500 mTorr, the transistor may exhibit electrical characteristics suitable for use as the pixel transistor Tpx and/or the driver transistor Tdr depending on the content of indium (In) of the active layer, or may operate substantially like a conductor. For example, when the deposition pressure of the gate insulating layer GI is about 1400 mTorr or about 1500 mTorr and the content of indium (In) of the active layer is about 40 at % or about 54 at %, the transistor may exhibit electrical characteristics (e.g., the threshold voltage Vth and mobility μ suitable for use as the pixel transistor Tpx and/or the driver transistor Tdr) suitable for use as the pixel transistor Tpx and/or the driver transistor Tdr. In an embodiment, the threshold voltage range Vth of a transistor suitable for use as the pixel transistor Tpx and the driver transistor Tdr may be about −1 V to about 0.5 V, and the mobility μ range may be about 20 cm²/Vs to about 50 cm²/Vs. However, this may vary depending on the design conditions of the display panel 110, the driving conditions of the pixel transistor Tpx and/or the driver transistor Tdr.

In an embodiment, when the content of indium (In) of the active layer is greater than about 54 at %, for example, in the case that the content of indium (In) of the active layer is about 60 at %, the carrier concentration of the active layer is excessively large, and the transistor may exhibit the same operating characteristics as a conductor. For example, although the deposition pressure of the gate insulating layer GI is about 1400 mTorr or about 1500 mTorr, in a case where the content of indium (In) of the active layer is about 60 at %, the transistor may operate like a conductor.

In an embodiment, based on the experimental results of FIGS. 7 and 8, the content of indium (In) of the active layer constituting each transistor and the deposition pressure of the gate insulating layer GI may be appropriately set and/or limited. For example, by setting or controlling the content of indium (In) of the active layer to about 54 at % or less, element characteristics (e.g., electrical characteristics) of a transistor suitable for use as the pixel transistor Tpx and/or the driver transistor Tdr may be secured. Additionally, in an embodiment, by setting or controlling the content of indium (In) of the active layer to about 40 at % or more, although the transistor is formed in a fine size in the high-resolution display device 100 or the like, the carrier concentration of the transistor may be controlled to a certain degree such that appropriate mobility may be secured and power consumption may be improved. For example, when the content of indium (In) of the active layer is less than about 40 at %, the carrier concentration in the active layer is low, so that power consumption may increase and/or the size of the transistor may need to be expanded to secure the characteristics of the transistor. On the other hand, in other embodiments, by controlling the content of indium (In) of the active layer to about 40 at % or more, the formation area of the transistor may be reduced, and the power consumption of the display device 100 may be improved.

In addition, in an embodiment, by limiting the deposition pressure of the gate insulating layer GI to about 1400 mTorr or more, the electrical characteristics of the transistor may be secured to a degree suitable for use as the pixel transistor Tpx and/or the driver transistor Tdr. Additionally, by limiting the deposition pressure of the gate insulating layer GI to about 1500 mTorr or less, the reliability of the transistor manufactured through this may be secured. For example, when the deposition pressure of the gate insulating layer GI is more than about 1600 mTorr, it may be difficult to ensure the reliability of the transistor manufactured through this, or the conductivity of the active layer may be excessively reduced. On the other hand, in an embodiment, the reliability and element characteristics of the transistor may be secured by controlling the deposition pressure of the gate insulating layer GI to about 1500 mTorr or less.

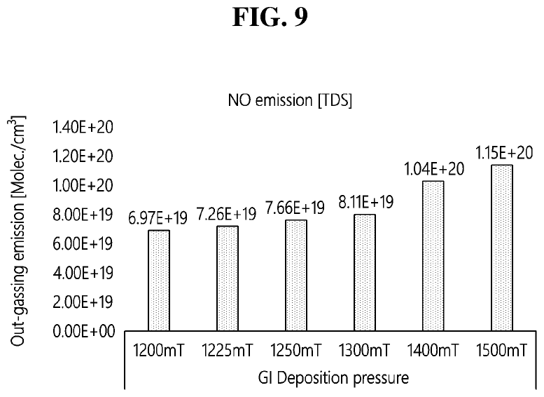

In an embodiment, FIG. 9 illustrates the emission amount of nitrogen monoxide (NO) according to the deposition pressure of the gate insulating layer GI. For example, FIG. 9 illustrates the results of measuring the emission amount of nitrogen monoxide (NO) from the gate insulating layer GI according to the deposition pressure of the gate insulating layer GI in the analysis by thermal desorption spectroscopy (TDS).

In an embodiment and referring to FIG. 9 in addition to FIGS. 1 to 8, the gate insulating layer GI deposited at a pressure of each of about 1200 mTorr (mT), about 1225 mTorr, about 1250 mTorr, about 1300 mTorr, about 1400 mTorr, and about 1500 mTorr may emit nitrogen monoxide (NO) at different concentrations depending on the deposition pressure in the analysis by thermal desorption spectroscopy (TDS). As in the previously described embodiments, the gate insulating layer GI deposited at a pressure range of about 1400 mTorr to about 1500 mTorr may emit nitrogen monoxide (NO) in the range of about 1.04E+20 Molec./cm³ to about 1.15E+20 Molec./cm³. In an embodiment, the analysis by thermal desorption spectroscopy (TDS) may be conducted under heat treatment conditions performed at a temperature range of about 50° C. or more and about 550° C. or less, and the thickness of the gate insulating layer GI used for the measurement may be approximately 1400 Å.

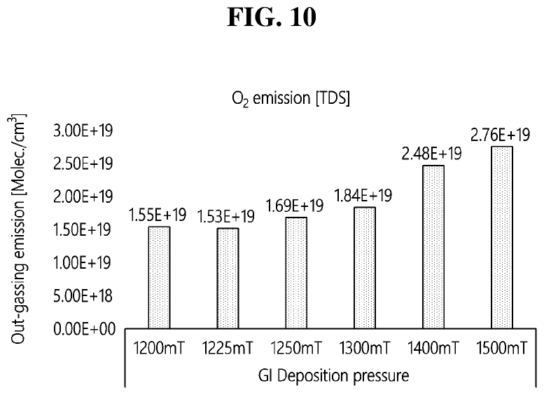

In an embodiment, FIG. 10 illustrates the emission amount of oxygen (O₂) according to the deposition pressure of the gate insulating layer GI. For example, FIG. 10 illustrates the results of measuring the emission amount of oxygen (O₂) from the gate insulating layer GI according to the deposition pressure of the gate insulating layer GI in the analysis by thermal desorption spectroscopy (TDS).

Referring to FIG. 10 in addition to FIGS. 1 to 9, the gate insulating layer GI deposited at a pressure of each of about 1200 mTorr (mT), about 1225 mTorr, about 1250 mTorr, about 1300 mTorr, about 1400 mTorr, and about 1500 mTorr may emit oxygen (O₂) at different concentrations depending on the deposition pressure in the analysis by thermal desorption spectroscopy (TDS). As in the previously described embodiments, the gate insulating layer GI deposited at a pressure range of about 1400 mTorr to about 1500 mTorr may emit oxygen (O₂) in the range of about 2.48E+19 Molec./cm³ to about 2.76E+19 Molec./cm³. In an embodiment, the analysis by thermal desorption spectroscopy (TDS) may be conducted under heat treatment conditions performed at a temperature range of about 50° C. or more and about 550° C. or less, and the thickness of the gate insulating layer GI used for the measurement may be approximately 1400 Å.

In an embodiment and as described above, each transistor (e.g., the first transistor T1, the second transistor T2, or the third transistor T3) may include an active layer including an oxide semiconductor containing indium (In) at a content range of about 40 at % to about 54 at %. In addition, the gate insulating layer disposed on the active layer may have characteristics with an emission amount range of nitrogen monoxide (NO) of about 1.04E+20 Molec./cm³ to about 1.15E+20 Molec./cm³ or an emission amount range of oxygen (O₂) of about 2.48E+19 Molec./cm³ to about 2.76E+19 Molec./cm³.

In an embodiment, in the data disclosed in FIGS. 7 to 10, the characteristics of the gate insulating layer GI are controlled by controlling the deposition pressure of the gate insulating layer GI in relation to the deposition conditions (e.g., chemical vapor deposition (CVD) parameters) of the gate insulating layer GI, but the invention is not limited thereto. For example, at least one of the deposition pressure of the gate insulating layer GI, the deposition power, the distance between the deposition device and the target substrate (e.g., the substrate SUB provided with the first and second active layers ACT1 and ACT2, respectively), or the flow rate ratios of the deposition gas is adjusted, so that the gate insulating layer GI may be formed such that the emission amount of nitrogen monoxide (NO) and/or the emission amount of oxygen (O₂) of the gate insulating layer GI falls within the exemplified range.

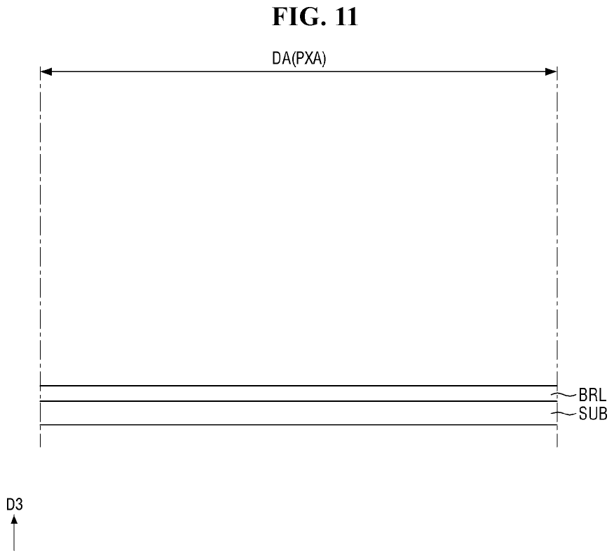

FIGS. 11 to 18 are cross-sectional views illustrating a method for manufacturing the display device 100, according to an embodiment. For example, FIGS. 11 to 18 sequentially illustrate steps of forming the pixel transistors Tpx on the substrate SUB among the steps of manufacturing the display panel 110 of FIG. 4 or FIG. 5. In an embodiment, the driver transistors Tdr including the third transistor T3 may be formed simultaneously with the pixel transistors Tpx in a substantially same or similar manner as the pixel transistors Tpx. However, in the step of forming the first conductive layer CDL1, respective lower electrodes may be formed or may not be formed on the driver transistors Tdr.

In an embodiment and referring to FIG. 11 in addition to FIGS. 1 to 10, the substrate SUB including at least the display area DA may be prepared. The display area DA may include the pixel area PXA.

In an embodiment, the barrier layer BRL may be formed on the substrate SUB. The barrier layer BRL may be formed through a film forming process (e.g., deposition process) of an insulating layer using at least one insulating material (e.g., an inorganic insulating material) exemplified above. Materials and/or methods for forming the barrier layer BRL may be variously changed according to embodiments.

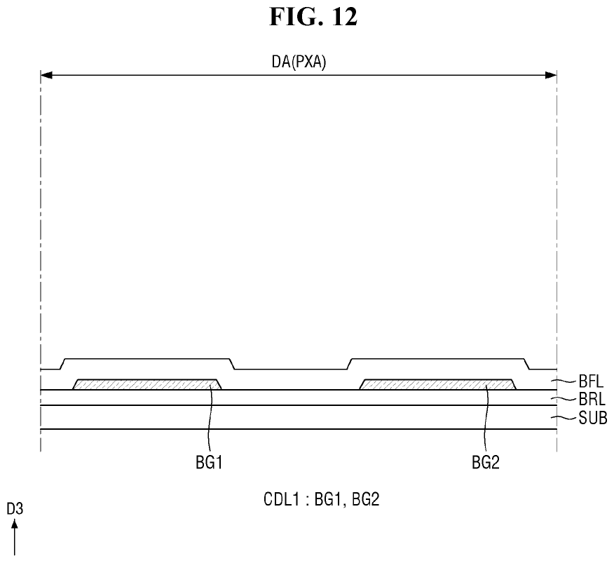

In an embodiment and referring to FIG. 12 in addition to FIGS. 1 to 11, the first conductive layer CDL1 including at least one lower electrode may be formed on the substrate SUB. For example, the first lower electrode BG1 and the second lower electrode BG2 may be formed on the barrier layer BRL on the substrate SUB. The first lower electrode BG1 and the second lower electrode BG2 may be formed in each of the pixel areas PXA.

In an embodiment, the first lower electrode BG1 and the second lower electrode BG2 may be formed through a film forming process (e.g., deposition process) of a conductive layer by using at least one conductive material exemplified above and a patterning process (e.g., an etching process using a mask) of the conductive layer. Materials and/or methods for forming the first lower electrode BG1 and the second lower electrode BG2 may be variously changed according to embodiments.

In an embodiment, the buffer layer BFL covering the first conductive layer CDL1 may be formed on the substrate SUB. The buffer layer BFL may be formed through a film forming process of an insulating layer using at least one insulating material (e.g., an inorganic insulating material) exemplified above. Materials and/or methods for forming the buffer layer BFL may be variously changed according to embodiments.

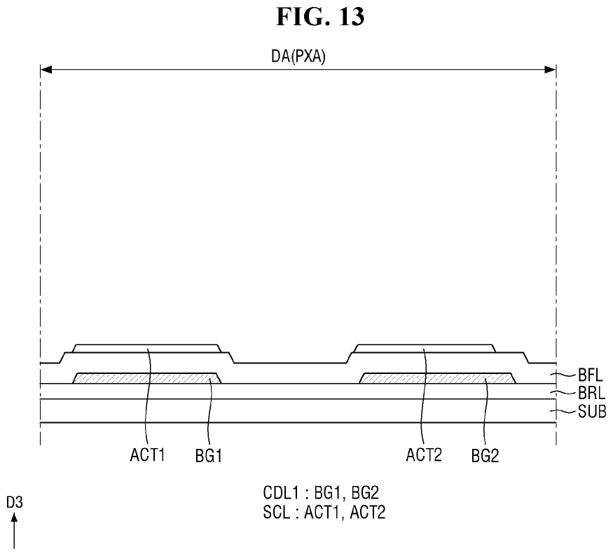

In an embodiment and referring to FIG. 13 in addition to FIGS. 1 to 12, the semiconductor layer SCL including the first active layer ACT1 and the second active layer ACT2 may be formed on the buffer layer BFL. For example, the first active layer ACT1 and the second active layer ACT2 may be formed in each of the pixel areas PXA. The first active layers ACT1 may be formed to overlap the first lower electrodes BG1 and the second active layers ACT2 may be formed to overlap the second lower electrodes BG2.

In an embodiment, the active layers ACT provided in the semiconductor layer SCL may be formed simultaneously using the same oxide semiconductor. For example, the first active layer ACT1 and the second active layer ACT2 may be formed simultaneously using the same oxide semiconductor. For example, the first active layer ACT1 and the second active layer ACT2 may be formed in the pixel area PXA through the film forming process and patterning process of the oxide semiconductor layer using at least one oxide semiconductor exemplified above.

In an embodiment, the first active layer ACT1 and the second active layer ACT2 may be formed using an oxide semiconductor containing indium (In) at a content range of about 40 at % to about 54 at %. For example, by controlling the indium (In) ratio of the sputtering target made of an oxide semiconductor containing indium (In) to a range of about 40 at % to about 54 at %, each of the first active layer ACT1 and the second active layer ACT2 containing indium (In) at a content range of about 40 at % to about 54 at % may be formed.

In an embodiment, when the display panel 110 further includes the third transistor T3 illustrated in FIG. 6, the first and second active layers ACT1 and ACT2 may be formed in the pixel area PXA, and at the same time, the third active layer ACT3 may be formed in the driving circuit area DRA. For example, the third active layer ACT3 may be formed on the buffer layer BFL in the driving circuit area DRA by using the same oxide semiconductor as the first and second active layers ACT1 and ACT2.

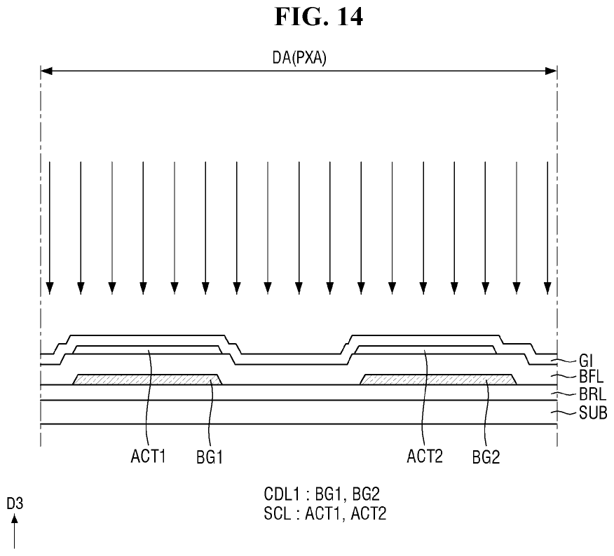

In an embodiment and referring to FIG. 14 in addition to FIGS. 1 to 13, the gate insulating layer GI covering the semiconductor layer SCL may be formed on the substrate SUB. For example, the gate insulating layer GI may be formed on the active layers (e.g., the first active layer ACT1, the second active layer ACT2, and/or the third active layer ACT3) provided on the semiconductor layer SCL.

In an embodiment, the gate insulating layer GI may first be formed entirely on the substrate SUB provided with the first and second active layers ACT1 and ACT2. For example, after forming the gate insulating layer GI by depositing an oxide-containing insulating material (e.g., silicon oxide) on the substrate SUB on which the semiconductor layer SCL is formed, a subsequent process such as heat treatment (e.g., annealing) may be performed. In an embodiment, the deposition conditions of the gate insulating layer GI may be controlled such that the emission amount of nitrogen monoxide (NO) of the gate insulating layer GI is in the range of about 1.04E+20 Molec./cm³ to about 1.15E+20 Molec./cm³ and/or the emission amount of oxygen (O₂) of the gate insulating layer GI is in the range of about 2.48E+19 Molec./cm³ to about 2.76E+19 Molec./cm³.

In an embodiment, the deposition conditions for controlling the film quality of the gate insulating layer GI may be at least one of the deposition pressure, the deposition power, the distance between the deposition device and the target substrate (e.g., the substrates SUB provided with the first and second active layers ACT1 and ACT2), or the flow rate ratio of the deposition gas. For example, by depositing an oxide-containing insulating material (e.g., silicon oxide) at a pressure range of about 1400 mTorr to about 1500 mTorr, the gate insulating layer GI may be formed such that the gate insulating layer GI has characteristics that satisfy the above-mentioned gas emission amount.

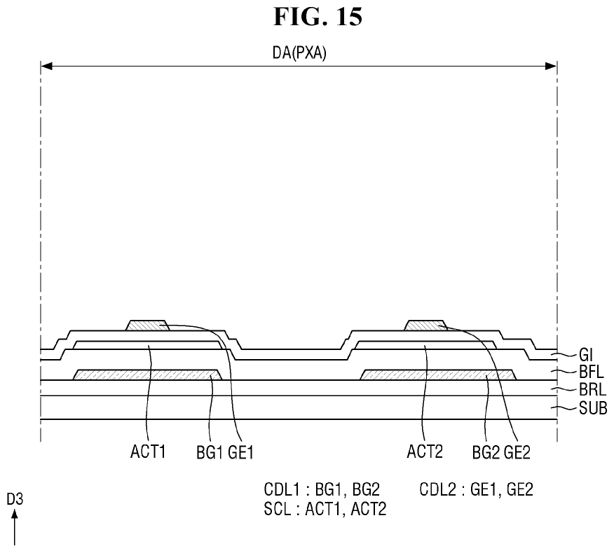

In an embodiment and referring to FIG. 15 in addition to FIGS. 1 to 14, the second conductive layer CDL2 including the first gate electrode GE1 and the second gate electrode GE2 may be formed on the gate insulating layer GI. For example, in each of the pixel areas PXA, the first gate electrode GE1 may be formed on the first active layer ACT1 to overlap a part of the first active layer ACT1, and the second gate electrode GE2 may be formed on the second active layer ACT2 to overlap a part of the second active layer ACT2.

In an embodiment, the first gate electrode GE1 and the second gate electrode GE2 provided in the second conductive layer CDL2 may be formed simultaneously using the same conductive material. For example, the first gate electrode GE1 and the second gate electrode GE2 may be formed simultaneously through the film forming process of a conductive layer by using at least one conductive material exemplified above and the patterning process of the conductive layer. Materials and/or methods for forming the first gate electrode GE1 and the second gate electrode GE2 may be variously changed according to embodiments.

In an embodiment, when the display panel 110 further includes the third transistor T3 illustrated in FIG. 6, the first and second gate electrodes GE1 and GE2 may be formed in the pixel area PXA, and at the same time, the third gate electrode GE3 may be formed in the driving circuit area DRA. For example, the third gate electrode GE3 may be formed in the driving circuit area DRA by using the same conductive material as the first gate electrode GE1 and the second gate electrode GE2.

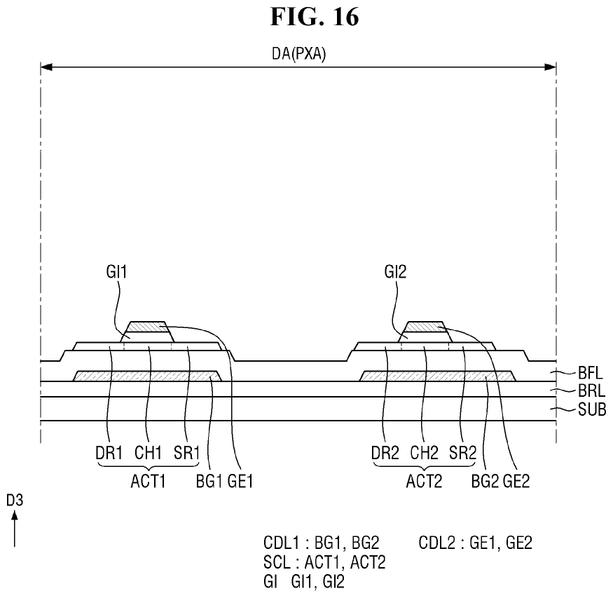

In an embodiment and referring to FIG. 16 in addition to FIGS. 1 to 15, the gate insulating layer GI may be etched to have a shape corresponding to that of each gate electrode. As a result, the first gate insulating layer GI1 overlapping the first gate electrode GE1 and the second gate insulating layer GI2 overlapping the second gate electrode GE2 may be formed separately. For example, the gate insulating layer GI may be etched by utilizing a mask used for patterning the first gate electrode GE1 and the second gate electrode GE2 or utilizing the first gate electrode GE1 and the second gate electrode GE2 as a mask. Accordingly, the first gate insulating layer GI1 and the second gate insulating layer GI2 may be formed under the first gate electrode GE1 and the second gate electrode GE2, respectively. The first gate insulating layer GI1 may be formed on a portion of the first active layer ACT1 that overlaps the first gate electrode GE1 and may have a shape and/or a size corresponding to the shape and/or size of the first gate electrode GE1. The second gate insulating layer GI2 may be formed on a portion of the second active layer ACT2 that overlaps the second gate electrode GE2 and may have a shape and/or a size corresponding to the shape and/or size of the second gate electrode GE2.

In an embodiment, in the process of forming the first gate insulating layer GI1 and the second gate insulating layer GI2 by etching the gate insulating layer GI, the properties of the first active layer ACT1 and the second active layer ACT2 may be changed such that the first active layer ACT1 and the second active layer ACT2 have different characteristics for each portion. Accordingly, each of the first active layer ACT1 and the second active layer ACT2 may be divided into a plurality of areas having different characteristics.

For example, in an embodiment, mainly at a portion that does not overlap the first gate electrode GE1, oxygen vacancy may occur in the oxide semiconductor forming the first active layer ACT1 due to an etching gas or the like. In an embodiment, oxygen vacancy may occur mainly at a portion (e.g., the first drain region DR1 and the first source region SR1) of the first active layer ACT1 that does not overlap the first gate electrode GE1. Oxygen vacancy in the first active layer ACT1 may diffuse to a portion of the area that overlaps the first gate electrode GE1. Accordingly, the first active layer ACT1 may be divided into a plurality of regions (e.g., the first channel region CH1, the first drain region DR1, and the first source region SR1) having different characteristics.

Similarly, in an embodiment, mainly at a portion that does not overlap the second gate electrode GE2, oxygen vacancy may occur in the oxide semiconductor that forms the second active layer ACT2. Accordingly, the second active layer ACT2 may be divided into a plurality of regions (e.g., the second channel region CH2, the second drain region DR2, and the second source region SR2) having different characteristics.

In another embodiment, the gate insulating layer GI may not be etched into a shape corresponding to the first gate electrode GE1 and/or the second gate electrode GE2, and the gate insulating layer GI may be formed to entirely cover the display area DA or the like. In an embodiment, the process of doping a portion (e.g., the first drain region DR1 and the first source region SR1) of the first active layer ACT1 that is not covered by the first gate electrode GE1, and/or a portion (e.g., the second drain region DR2 and the second source region SR2) of the second active layer ACT2 that is not covered by the second gate electrode GE2 to make them conductive may be additionally performed. In another embodiment, the doping process may not be performed. In this case, hydrogen is introduced into the first drain region DR1, the first source region SR1, the second drain region DR2, and the second source region SR2 during the subsequent forming process of the interlayer insulating layer ILD, so that the first drain region DR1, the first source region SR1, the second drain region DR2, and the second source region SR2 may become conductive.

In an embodiment, when the display panel 110 further includes the third transistor T3 illustrated in FIG. 6, the first and second gate insulating layers GI1 and GI2 may be formed in the pixel area PXA, and at the same time, the third gate insulating layer GI3 may be formed in the driving circuit area DRA. For example, the gate insulating layer GI may be formed entirely and may be etched and patterned into the first gate insulating layer GI1, the second gate insulating layer GI3, and the third gate insulating layer GI3.

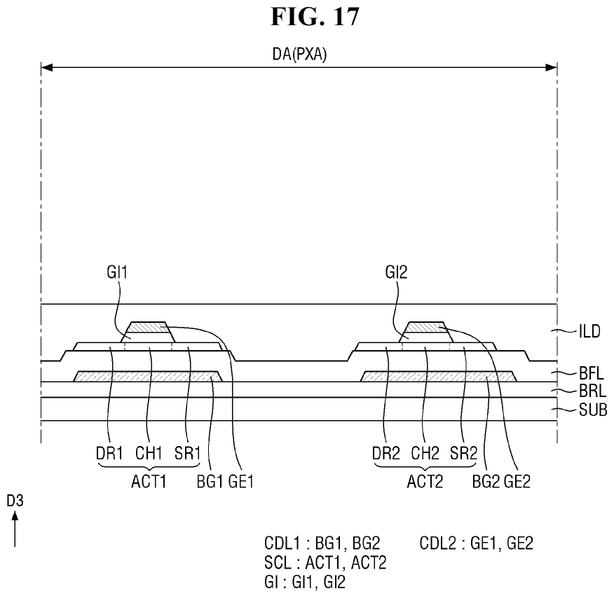

In an embodiment and referring to FIG. 17 in addition to FIGS. 1 to 16, the active layers (e.g., the first active layer ACT1 and the second active layer ACT2) provided on the semiconductor layer SCL, and the interlayer insulating layer ILD that covers the gate electrodes (e.g., the first gate electrode GE1 and the second gate electrode GE2) provided on the second conductive layer CDL2 may be formed on the buffer layer BFL. The interlayer insulating layer ILD may be formed through the film forming process of an insulating layer by using at least one insulating material (e.g., an inorganic insulating material) exemplified above. In an embodiment, after forming the interlayer insulating layer ILD, a subsequent process such as heat treatment may be performed. Materials and/or methods for forming the interlayer insulating layer ILD may be variously changed according to embodiments.

In an embodiment, in the process of forming the interlayer insulating layer ILD, hydrogen may be introduced into the active layers of the semiconductor layer SCL including the first active layer ACT1 and the second active layer ACT2. As hydrogen is introduced into the first active layer ACT1 and the second active layer ACT2, mainly at the portion containing a large number of oxygen vacancies, the first active layer ACT1 and the second active layer ACT2 may partially become conductive (e.g., N type). For example, the first drain region DR1, the first source region SR1, the second drain region DR2, and the second source region SR2 may become conductive. In an embodiment, when the display panel 110 further includes the third transistor T3 illustrated in FIG. 6, the third drain region DR3 and the third source region SR3 may also become conductive.

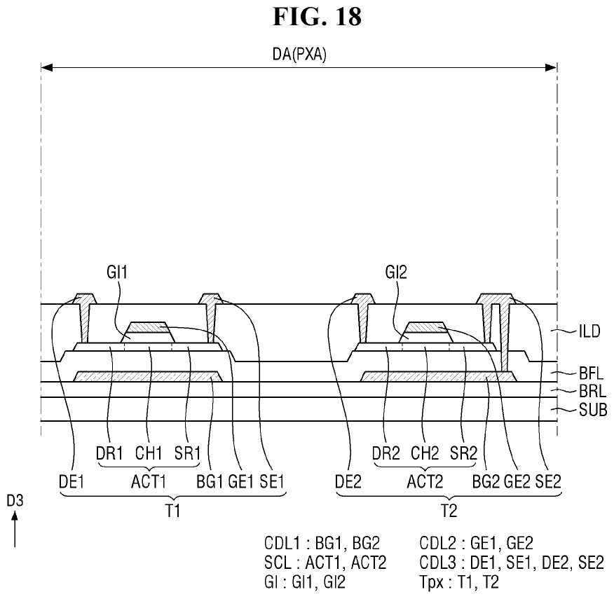

In an embodiment and referring to FIG. 18 in addition to FIGS. 1 to 17, the first drain electrode DE1, the first source electrode SE1, the second drain electrode DE2, and the second source electrode SE2 may be formed on the interlayer insulating layer ILD. In an embodiment, when at least one of the first drain region DR1, the first source region SR1, the second drain region DR2, or the second source region SR2 replaces at least one of the first drain electrode DE1, the first source electrode SE1, the second drain electrode DE2, or the second source electrode SE2, respectively, at least one of the first drain electrode DE1, the first source electrode SE1, the second drain electrode DE2, or the second source electrode SE2 may not be formed.

In an embodiment, the first drain electrode DE1 and the first source electrode SE1 may be formed to be connected to different parts of the first active layer ACT1. For example, the first drain electrode DE1 may be formed to be connected to the first drain region DR1, and the first source electrode SE1 may be formed to be connected to the first source region SR1. The second drain electrode DE2 and the second source electrode SE2 may be formed to be connected to different parts of the second active layer ACT2. For example, the second drain electrode DE2 may be formed to be connected to the second drain region DR2, and the second source electrode SE2 may be formed to be connected to the second source region SR2. To this end, prior to the formation of the first drain electrode DE1, the first source electrode SE1, the second drain electrode DE2, and the second source electrode SE2, a plurality of contact holes may be formed in the interlayer insulating layer ILD.

In an embodiment, when the display panel 110 further includes the third transistor T3 illustrated in FIG. 6, the first and second drain electrodes DE1 and DE2, respectively, and the first and second source electrodes SE1 and SE2, respectively, are formed in the pixel area PXA, and at the same time, the third drain electrode DE3 and the third source electrode SE3 may be formed in the driving circuit area DRA. For example, the conductive layer formed on the interlayer insulating layer ILD may be etched and may be patterned to form the first, second, and third drain electrodes DE1, DE2, and DE3, respectively, and the first, second, and third source electrodes SE1, SE2, and SE3, respectively.

In an embodiment, through the above-described process, a plurality of pixel transistors Tpx including the first transistor T1 and the second transistor T2 may be formed in the display area DA. In an embodiment in which the display panel 110 includes the driving circuit area DRA, the plurality of driver transistors Tdr including the third transistor T3 may be formed in the driving circuit area DRA. In an embodiment, elements provided on the same conductive layer or the same semiconductor layer SCL of the display panel 110 may be formed simultaneously.

In an embodiment, after forming the pixel transistors Tpx and/or the driver transistors Tdr, a process of forming the first passivation layer PSV1 of FIGS. 4 and 5 may be performed. The first passivation layer PSV1 may cover the pixel transistors Tpx and/or the driver transistors Tdr. In an embodiment, a process of forming the fourth conductive layer CDL4 including the connection electrode CNE of each of the pixels PX on the first passivation layer PSV1, and a process of forming the second passivation layer PSV2 covering the fourth conductive layer CDL4 may be additionally performed. Accordingly, the panel circuit layer PCL of the display panel 110 may be formed.

In an embodiment, when the display panel 110 includes the light emitting element layer LEL and the encapsulation layer ENL disposed on the panel circuit layer PCL, the light emitting element layer LEL and the encapsulation layer ENL may be sequentially formed on the panel circuit layer PCL. Through the above-described processes, the display panel 110 and the display device 100 including the same according to an embodiment may be manufactured.

In concluding the detailed description, those skilled in the art will appreciate that many variations and modifications can be made to the invention without substantially departing from the scope of the invention. Therefore, the disclosed embodiments are used in a generic and descriptive sense only and not for purposes of limitation. The invention should not be construed as being limited to the embodiments set forth herein. Rather, these embodiments are provided so that this disclosure will be thorough and complete and will fully convey the concept of the invention to those skilled in the art. Moreover, the embodiments or parts of the embodiments may be combined in whole or in part without departing from the scope of the invention.

What is claimed is:

1. A display device comprising:
a substrate;
a first transistor comprising a first active layer disposed on the substrate and a first gate electrode disposed on the first active layer; and
a first gate insulating layer disposed between the first active layer and the first gate electrode,
wherein the first active layer comprises an oxide semiconductor containing indium (In) at a content range of about 40 at % to about 54 at %, and
wherein the first gate insulating layer has an emission amount range of oxygen (O₂) of about 2.48E+19 Molec./cm³ to about 2.76E+19 Molec./cm³, or an emission amount range of nitrogen monoxide (NO) of about 1.04E+20 Molec./cm³ to about 1.15E+20 Molec./cm³ under heat treatment conditions performed at a temperature range of about 50° C. to about 550° C.

2. The display device of claim 1, wherein the first active layer further contains at least one of gallium (Ga), zinc (Zn), and tin (Sn).

3. The display device of claim 2, wherein the first active layer contains indium-gallium-zinc oxide (IGZO), indium-tin-gallium oxide (ITGO), or indium-tin-gallium-zinc oxide (ITGZO).

4. The display device of claim 1, wherein the first gate insulating layer contains silicon oxide.

5. The display device of claim 1, further comprising a pixel, wherein the pixel comprises a pixel circuit comprising the first transistor and a light emitting element connected to the pixel circuit.

6. The display device of claim 5, wherein the pixel further comprises:
a second transistor comprising a second active layer disposed on the substrate and a second gate electrode disposed on the second active layer; and
a second gate insulating layer disposed between the second active layer and the second gate electrode.

7. The display device of claim 6, wherein the second active layer is disposed in a same layer as the first active layer, wherein the second active layer contains a same oxide semiconductor as the first active layer.

8. The display device of claim 6, wherein the second gate insulating layer is disposed in a same layer as the first gate insulating layer, wherein the second gate insulating layer contains a same insulating material as the first gate insulating layer.

9. The display device of claim 5, further comprising a driver disposed on the substrate and electrically connected to the pixel.

10. The display device of claim 9, wherein the driver comprises:
a third transistor comprising a third active layer disposed on the substrate and containing a same oxide semiconductor as the first active layer, wherein a third gate electrode is disposed on the third active layer; and
a third gate insulating layer disposed between the third active layer and the third gate electrode and containing a same insulating material as the first gate insulating layer.

11. The display device of claim 1, wherein the first active layer comprises a first channel region overlapping the first gate electrode, and a first drain region and a first source region located on both sides of the first channel region, wherein
the first gate insulating layer is an insulating pattern disposed only on a portion of the first active layer comprising the first channel region and exposing the first drain region and the first source region.

12. The display device of claim 1, further comprising an interlayer insulating layer disposed on the substrate and covering the first active layer and the first gate electrode,
wherein the first transistor further comprises at least one of a first drain electrode disposed on the interlayer insulating layer and connected to a part of the first active layer, and a first source electrode disposed on the interlayer insulating layer and connected to another part of the first active layer.

13. The display device of claim 12, further comprising a first passivation layer disposed on the interlayer insulating layer and covering the first transistor.

14. The display device of claim 13, wherein the first passivation layer comprises an inorganic insulating layer containing silicon nitride.

15. The display device of claim 13, further comprising a second passivation layer disposed on the first passivation layer,
wherein the first passivation layer comprises an inorganic insulating layer containing silicon oxide, and
wherein the second passivation layer comprises an inorganic insulating layer containing silicon nitride.

16. The display device of claim 1, wherein the first transistor has an electron mobility in a range of about 20 cm²/Vs to about 50 cm²/Vs.

17. The display device of claim 1, wherein the first transistor has a threshold voltage in a range of about −1.0 V to about +0.5 V.

18. A method for manufacturing a display device, comprising:
forming an active layer on a substrate;
forming a gate insulating layer on the active layer; and
forming a gate electrode on the gate insulating layer,
wherein in the forming of the active layer, the active layer is formed using an oxide semiconductor containing indium (In) at a content range of about 40 at % to about 54 at %, and
wherein in the forming of the gate insulating layer, the gate insulating layer is formed by depositing an insulating material containing oxide on the substrate at a pressure range of about 1400 mTorr to about 1500 mTorr.

19. The method of claim 18, further comprising etching the gate insulating layer to have a shape corresponding to that of the gate electrode.

20. The method of claim 18, further comprising:
forming an interlayer insulating layer covering the active layer and the gate electrode; and
forming at least one of a drain electrode connected to a part of the active layer or a source electrode connected to another part of the active layer, on the interlayer insulating layer.
